(19) United States
(12) Patent Application Publication
(10) Pub. No.: US 2026/0223692 A1
(43) Pub. Date: Jul. 30, 2026

(54) SEMICONDUCTOR DEVICE

(71) Applicant: ROHM CO., LTD., Kyoto-shi (JP)

(72) Inventor: Naoyuki SANO, Kyoto-shi (JP)

(21) Appl. No.: 19/630,045

(22) Filed: Mar. 26, 2026

Related U.S. Application Data
(63) Continuation of application No. PCT/JP2024/035473, filed on Oct. 3, 2024.

(30) Foreign Application Priority Data
Oct. 4, 2023 (JP) 2023-173184

(51) Int. Cl. H10W 70/40; H10W 72/20; H10W 90/00

(52) U.S. Cl. CPC H10W 70/415; H10W 70/424; H10W 72/222; H10W 90/726

(57) ABSTRACT

A semiconductor device includes: terminals that include a terminal obverse surface and a terminal reverse surface; a semiconductor chip that is mounted on the terminals; and an encapsulating resin for encapsulating the terminals and the semiconductor chip. The terminals include: a terminal portion that includes a terminal portion reverse surface, which is exposed from the encapsulating resin on the terminal reverse surface; a mounting portion that extends from the terminal portion in a first direction orthogonal to a Z direction, which is the thickness direction of the terminal, and has the semiconductor chip mounted thereon; a groove portion that is provided at least in the mounting portion and extends in the first direction; and wall portions that are positioned at both ends in a second direction orthogonal to both the Z direction and the first direction by the groove portion and extend in the first direction.

### CROSS-REFERENCE TO RELATED APPLICATIONS

This application is a continuation of, and claims the benefit of priority from International Application No. PCT/JP2024/035473, filed on October 3, 2024, which claims the benefit of priority from Japanese Patent Application No. 2023-173184, filed on October 4, 2023, the entire contents of each are incorporated herein by reference.

### BACKGROUND

1. Field

The following description relates to a semiconductor device.

2. Description of Related Art

JP2020-188083A discloses a semiconductor device that includes a lead frame, a semiconductor element including pillars soldered to the lead frame, and a resin encapsulating the semiconductor element.

### BRIEF DESCRIPTION OF THE DRAWINGS

FIG. 1 is a schematic perspective view of a semiconductor device in accordance with a first embodiment.

FIG. 2 is a schematic plan view showing the internal structure of the semiconductor device shown in FIG. 1.

FIG. 3 is a schematic back view of the semiconductor device shown in FIG. 1.

FIG. 4 is a schematic cross-sectional view of the semiconductor device taken along line F4-F4 shown in FIG. 2.

FIG. 5 is a schematic cross-sectional view of the semiconductor device taken along line F5-F5 shown in FIG. 4.

FIG. 6 is a schematic plan view of terminals.

FIG. 7 is a schematic perspective view of one of the terminals.

FIG. 8 is a schematic plan view illustrating an exemplary manufacturing step of the semiconductor device in accordance with the first embodiment.

FIG. 9 is a schematic plan view illustrating a manufacturing step following the step of FIG. 8.

FIG. 10 is a schematic cross-sectional view of a lead frame taken along line F10-F10 shown in FIG. 9, illustrating a manufacturing step following the step of FIG. 9.

FIG. 11 is a schematic plan view illustrating a manufacturing step following the step of FIG. 10.

FIG. 12 is a schematic cross-sectional view of the semiconductor device taken along line F12-F12 shown in FIG. 11, illustrating a manufacturing step following the step of FIG. 11.

FIG. 13 is a schematic cross-sectional view illustrating a manufacturing step following the step of FIG. 12.

FIG. 14 is a schematic cross-sectional view illustrating a manufacturing step following the step of FIG. 13.

FIG. 15 is a schematic cross-sectional view of a semiconductor device in accordance with a second embodiment.

FIG. 16 is a schematic back view of terminals included in the semiconductor device in accordance with the second embodiment.

FIG. 17 is a schematic cross-sectional view of the semiconductor device taken along line F17-F17 shown in FIG. 15.

FIG. 18 is a schematic cross-sectional view of a semiconductor device in accordance with a third embodiment.

FIG. 19 is a schematic cross-sectional view of the semiconductor device taken along line F19-F19 shown in FIG. 18.

FIG. 20 is a schematic cross-sectional view of a semiconductor device in accordance with a fourth embodiment.

FIG. 21 is a schematic cross-sectional view of the semiconductor device taken along line F21-F21 shown in FIG. 20.

FIG. 22 is a schematic perspective view of one of terminals.

FIG. 23 is a schematic cross-sectional view of a semiconductor device in accordance with a fifth embodiment.

FIG. 24 is a schematic cross-sectional view of the semiconductor device taken along line F24-F24 shown in FIG. 23.

FIG. 25 is a schematic back view of one of terminals.

FIG. 26 is a schematic cross-sectional view of a semiconductor device in accordance with a sixth embodiment.

FIG. 27 is a schematic cross-sectional view of the semiconductor device taken along line F27-F27 shown in FIG. 26.

FIG. 28 is a schematic cross-sectional view of a semiconductor device in accordance with a seventh embodiment.

FIG. 29 is a schematic cross-sectional view of the semiconductor device taken along line F29-F29 shown in FIG. 28.

FIG. 30 is a schematic cross-sectional view illustrating an exemplary manufacturing step of the semiconductor device in accordance with the seventh embodiment.

FIG. 31 is a schematic cross-sectional view illustrating a manufacturing step following the step of FIG. 30.

FIG. 32 is a schematic cross-sectional view illustrating a manufacturing step following the step of FIG. 31.

FIG. 33 is a schematic cross-sectional view illustrating a manufacturing step following the step of FIG. 32.

FIG. 34 is a schematic cross-sectional view illustrating a manufacturing step following the step of FIG. 33.

FIG. 35 is a schematic perspective view of one of terminals included in a semiconductor device of a modified example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Several embodiments of a semiconductor device according to the present disclosure will now be described with reference to the accompanying drawings. Elements in the drawings may not be drawn to scale for simplicity and clarity of illustration. In the cross-sectional drawings, hatching lines may not be shown in order to facilitate understanding. The accompanying drawings merely illustrate exemplary embodiments of the present disclosure and are not intended to limit the present disclosure.

This detailed description includes exemplary embodiments of devices, systems, and methods in accordance with the present disclosure. The present description is illustrative and is not intended to limit the embodiments of the present disclosure or application and use of the embodiments.

In this specification, the phrase “at least one of” as used in this disclosure means “one or more” of desired options. In an example, the phrase “at least one of” means “only one of two options” or “both of two options” if the number of options is two. In another example, the phrase “at least one of” means “only one of the options” or “any combination of two or more of the options” if the number of options is three or more.

In this specification, phrases such as “the dimension (depth, width, length, height) of A is equal to the dimension (depth, width, length, height) of B,” and “A and B have the same dimension (depth, width, length, height)” includes a relationship in which the difference between the dimension (depth, width, length, height) of A and the dimension (depth, width, length, height) of B is, for example, within 10% of the dimension (depth, width, length, height) of A.

### First Embodiment

### Overall Structure of Semiconductor Device

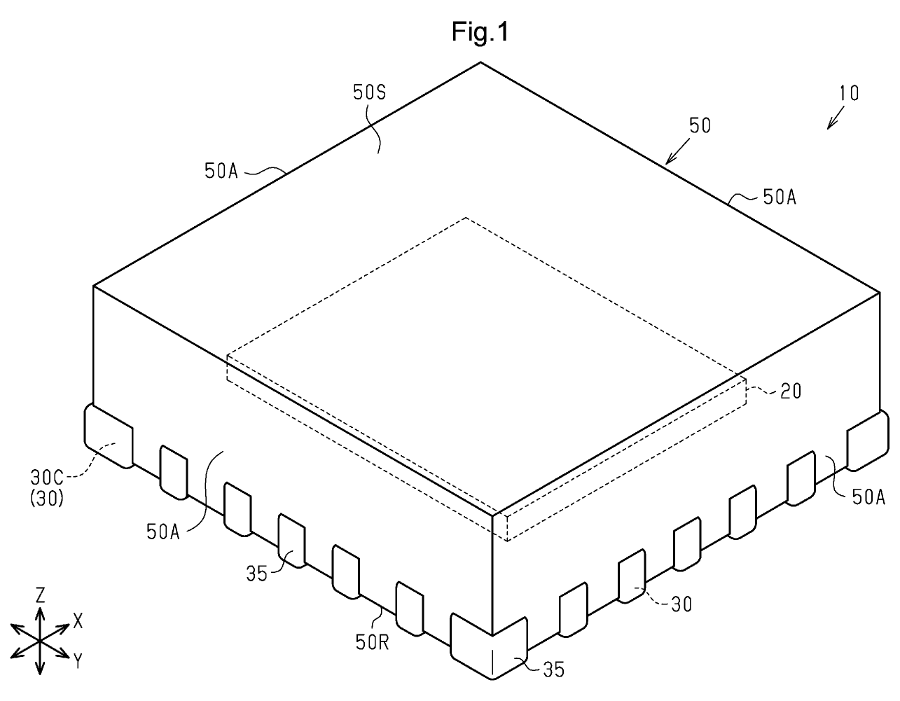

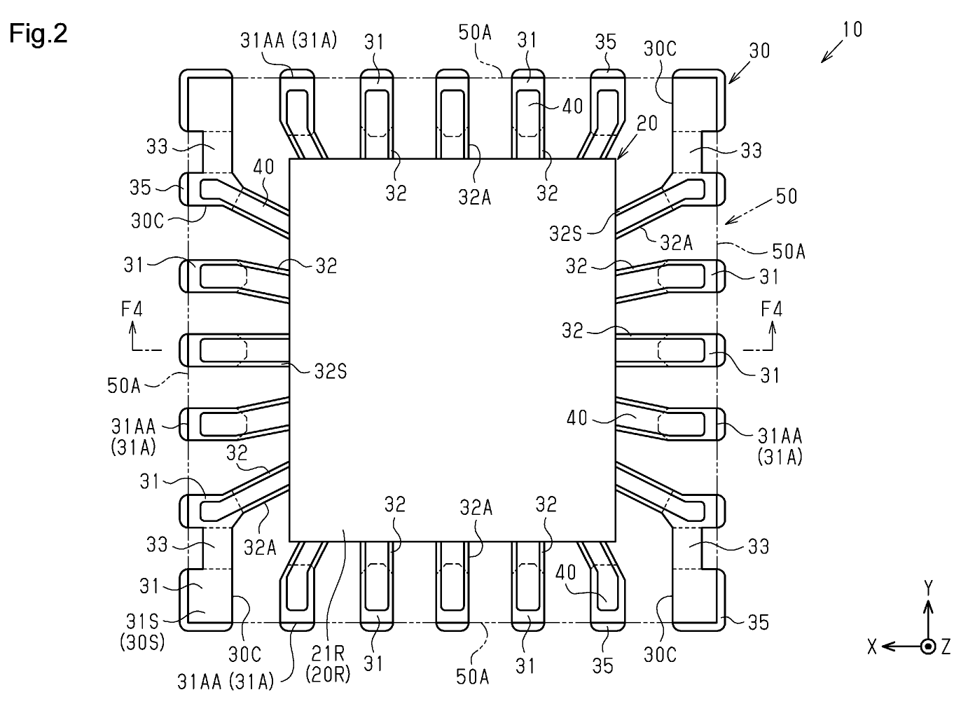

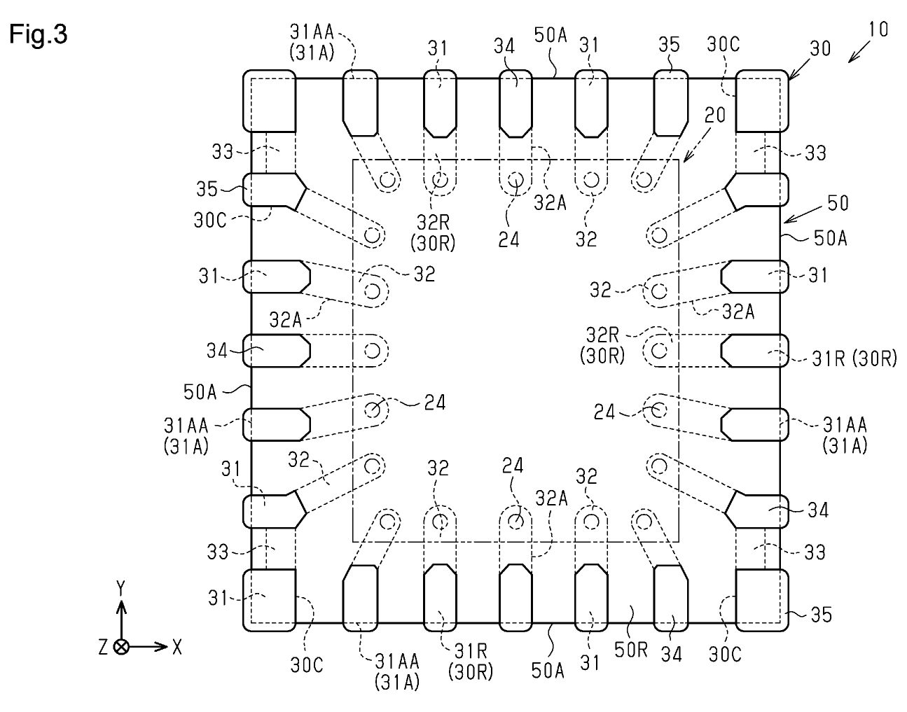

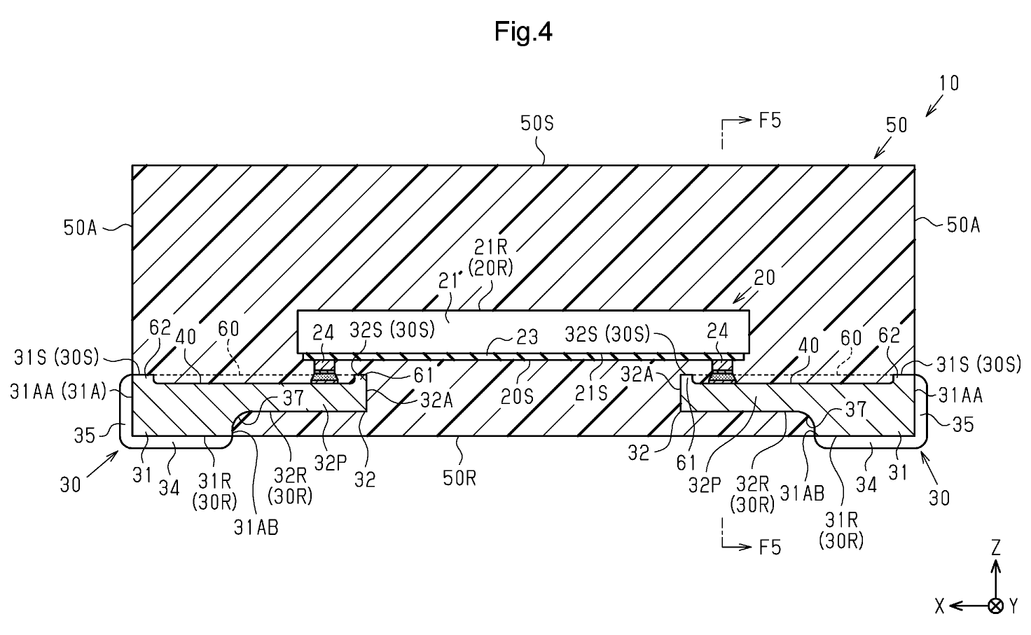

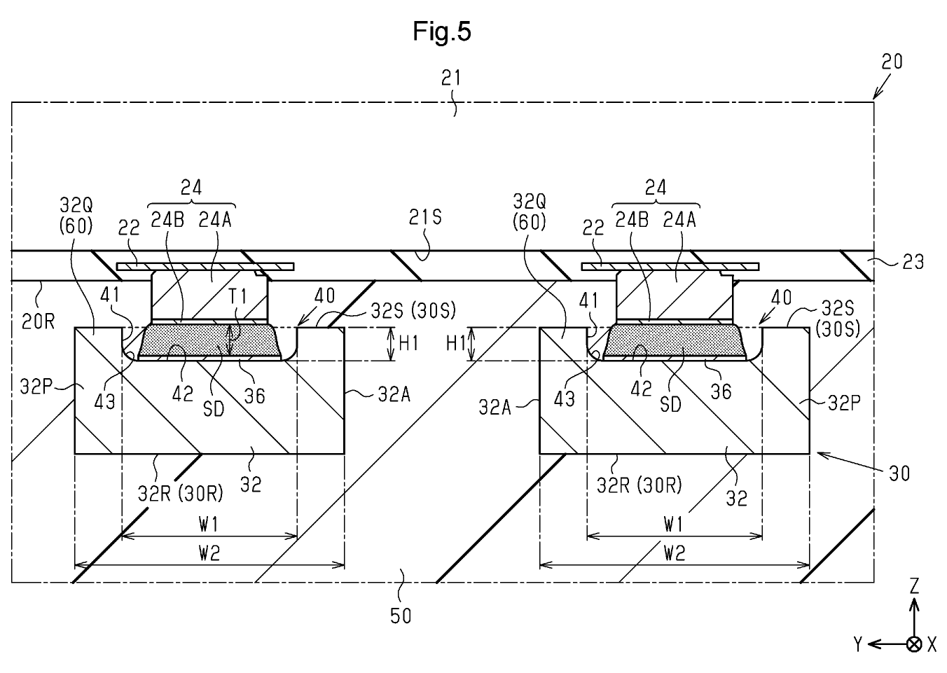

The overall structure of a semiconductor device 10 in accordance with a first embodiment will now be described with reference to FIGS. 1 to 5. FIG. 1 is a schematic perspective view showing the structure of the semiconductor device 10. FIG. 2 is a schematic plan view showing the internal structure of the semiconductor device 10. FIG. 3 is schematic back view showing the structure of the semiconductor device 10. FIG. 4 is a schematic cross-sectional view taken along line F4-F4 shown in FIG. 2, showing the structure of the semiconductor device 10. FIG. 5 is a schematic cross-sectional view taken along line F5-F5 shown in FIG. 4, showing the structure of the semiconductor device 10. In FIG. 1, broken lines indicate a semiconductor chip 20, which will be described later. In FIG. 2, double-dashed lines indicate an encapsulation resin 50, which will be described later. In FIG. 3, double-dashed lines indicate the semiconductor chip 20. In this specification, X-axis, Y-axis, and Z-axis are orthogonal to one another as shown in FIG. 1. The term “plan view” as used in this disclosure refers to a view of the semiconductor device 10 or elements of the semiconductor device 10 taken in the Z-direction.

As shown in FIG. 1, the semiconductor device 10 includes the semiconductor chip 20, terminals 30, and the encapsulation resin 50. The semiconductor chip 20 is mounted on the terminals 30. The encapsulation resin 50 encapsulates the semiconductor chip 20 and the terminals 30. Each of the terminals 30 is partially exposed from the encapsulation resin 50.

The encapsulation resin 50 defines a device head surface, a device back surface, and device side surfaces of the semiconductor device 10. The encapsulation resin 50 has a rectangular plate shape and has a thickness-wise direction parallel to the Z-direction. In other words, the semiconductor device 10 has a rectangular plate shape and has a thickness-wise direction parallel to the Z-direction.

The encapsulation resin 50 includes an encapsulation head surface 50S, an encapsulation back surface 50R, and four encapsulation side surfaces 50A. The encapsulation head surface 50S and the encapsulation back surface 50R face away from each other in the Z-direction. The four encapsulation side surfaces 50A connect the encapsulation head surface 50S and the encapsulation back surface 50R. The four encapsulation side surfaces 50A define the device side surfaces. The encapsulation resin 50 is formed from, for example, a black epoxy resin.

As shown in FIGS. 2 and 3, the terminals 30 each have a substantially flat plate shape and have a thickness-wise direction parallel to the Z-direction. In plan view, the terminals 30 are arranged along the four encapsulation side surfaces 50A. The terminals 30 each include a terminal head surface 30S, and a terminal back surface 30R facing away from the terminal head surface 30S. The terminal head surface 30S faces the same direction as the encapsulation head surface 50S, and the terminal back surface 30R faces the same direction as the encapsulation back surface 50R. Each terminal 30 is formed from, for example, a material containing copper (Cu), aluminum (Al), or the like. In the first embodiment, each terminal 30 is formed from a material containing Cu. The terminals 30 are formed by etching a metal plate containing Cu. In other words, the terminals 30 are formed by a metal lead frame.

The terminals 30 each include a terminal portion 31 and a mount portion 32. In an example, the terminal portion 31 and the mount portion 32 are integrally formed as an integrated structure. That is, the terminal portion 31 and the mount portion 32 are integrally formed from the same metal material.

The terminal portion 31 includes a terminal portion back surface 31R, a terminal portion head surface 31S, and terminal portion side surfaces 31A. The terminal portion back surface 31R is exposed from the encapsulation back surface 50R of the encapsulation resin 50. The terminal portion head surface 31S faces away from the terminal portion back surface 31R. The terminal portion side surfaces 31A connect the terminal portion head surface 31S and the terminal portion back surface 31R. The terminal portion back surface 31R defines part of the terminal back surface 30R. The terminal portion head surface 31S defines part of the terminal head surface 30S.

In plan view, the terminal portions 31 are located closer to the four encapsulation side surfaces 50A than the semiconductor chip 20 is. In other words, in plan view, the terminal portions 31 are located outward from the semiconductor chip 20. Accordingly, the semiconductor device 10 has a fan-out package structure.

In plan view, the terminal portions 31 of the terminals 30 are arranged along the four encapsulation side surfaces 50A. The terminal portion side surfaces 31A of each terminal portion 31 include a side surface that is flush with a corresponding one of the four encapsulation side surfaces 50A. This flush side surface defines an exposed side surface 31AA exposed from the corresponding one of the four encapsulation side surfaces 50A.

A back surface plating layer 34 is formed on the terminal portion back surface 31R of each terminal portion 31. In other words, each terminal 30 includes the back surface plating layer 34 covering the terminal portion back surface 31R of the terminal portion 31. The back surface plating layer 34 projects from the encapsulation back surface 50R. Further, a side surface plating layer 35 is formed on the exposed side surface 31AA of each terminal portion 31. In other words, each terminal 30 includes the side surface plating layer 35 covering the exposed side surface 31AA of the terminal portion 31. The side surface plating layer 35 projects from the encapsulation side surface 50A. In the first embodiment, the back surface plating layer 34 is integrated with the side surface plating layer 35. The back surface plating layer 34 and the side surface plating layer 35 each contain, for example, at least one of gold (Au), nickel (Ni), tin (Sn), and palladium (Pd). The back surface plating layer 34 is an example of “back surface conductive film”, and the side surface plating layer 35 is an example of “side surface conductive film”.

The mount portion 32 is disposed in the encapsulation resin 50. The mount portion 32 extends from the terminal portion 31 in a direction orthogonal to the Z-direction. Hereafter, the direction in which the mount portion 32 extends in plan view will be referred to as “the first direction”. In plan view, the mount portion 32 extends from the terminal portion 31 toward the semiconductor chip 20. In plan view, the mount portion 32 is located at a position that overlaps the semiconductor chip 20. A length of the mount portion 32 in the first direction is greater than a length of the terminal portion 31 in the first direction. In an example, the length of the mount portion 32 in the first direction may be greater than or equal to 1.5 times the length of the terminal portion 31 in the first direction. In an example, the length of the mount portion 32 in the first direction may be greater than or equal to twice the length of the terminal portion 31 in the first direction.

As shown in FIG. 4, the mount portion 32 is thinner than the terminal portion 31. The mount portion 32 includes a mount portion head surface 32S facing the same direction as the terminal portion head surface 31S, and a mount portion back surface 32R facing away from the mount portion head surface 32S. The mount portion head surface 32S defines part of the terminal head surface 30S, and the mount portion back surface 32R defines part of the terminal back surface 30R. In an example, the mount portion head surface 32S is flush with the terminal portion head surface 31S of the terminal portion 31. The terminal portion head surface 31S and the mount portion head surface 32S define the terminal head surface 30S. The terminal portion back surface 31R and the mount portion back surface 32R define the terminal back surface 30R. The mount portion 32 also includes a mount portion side surface 32A connecting the mount portion head surface 32S and the mount portion back surface 32R.

Each terminal 30 includes a curved surface 37. The curved surface 37 is located between the terminal portion 31 and the mount portion 32. More specifically, the terminal portion side surfaces 31A of the terminal portion 31 includes an inner side surface 31AB facing the mount portion 32 in the first direction. The curved surface 37 connects the inner side surface 31AB to the mount portion back surface 32R between the inner side surface 31AB and the mount portion back surface 32R.

As shown in FIG. 2, the terminals 30 disposed at four corners of the encapsulation resin 50 in plan view (hereafter, “corner terminals 30C”) each include two terminal portions 31. The two terminal portions 31 of the corner terminal 30C are located at the same position in the X-direction, and are separated from each other in the Y-direction. These terminal portions 31 are joined by a terminal joint 33.

As shown in FIGS. 2 to 4, the semiconductor chip 20 is mounted on the terminals 30. More specifically, the semiconductor chip 20 is mounted on the mount portions 32 of the terminals 30. The semiconductor chip 20 has a rectangular plate shape and has a thickness-wise direction parallel to the Z-direction. The semiconductor chip 20 includes a chip head surface 20S and a chip back surface 20R, facing away from each other in the Z-direction. The chip head surface 20S faces the mount portion head surface 32S of the mount portion 32. The chip back surface 20R faces the same direction as the mount portion head surface 32S.

The semiconductor chip 20 includes a semiconductor substrate 21 defining a chip main body. The semiconductor substrate 21 is formed from a material containing, for example, silicon (Si). The semiconductor chip 20 is, for example, a large scale integration (LSI) chip.

As shown in FIG. 4, the semiconductor substrate 21 includes a main body head surface 21S and a main body back surface 21R, facing away from each other in the Z-direction. The main body head surface 21S faces the same direction as the chip head surface 20S of the semiconductor chip 20. The main body back surface 21R faces the same direction as the chip back surface 20R. In the example shown in FIG. 4, the main body back surface 21R defines the chip back surface 20R.

As shown in FIGS. 4 and 5, the semiconductor chip 20 includes interconnects 22 arranged on the main body head surface 21S of the semiconductor substrate 21, and an insulating layer 23 covering the main body head surface 21S. The interconnects 22 are disposed on the semiconductor substrate 21 so as to face the mount portions 32 of the terminals 30 in the Z-direction. The insulating layer 23 includes openings that separately expose the interconnects 22 in the Z-direction. The interconnects 22 are formed from a material containing at least one of Al, Cu, Au, and titanium (Ti).

As shown in FIG. 5, the semiconductor chip 20 includes chip terminals 24 formed on the chip head surface 20S. The chip terminals 24 are separately bonded to the interconnects 22. More specifically, the chip terminals 24 are bonded to the interconnects 22 exposed from the openings of the insulating layer 23. Each chip terminal 24 is cylindrical and extends from the interconnect 22 in the Z-direction.

The chip terminal 24 includes a cylindrical terminal body 24A, and a barrier layer 24B formed on a distal end surface of the terminal body 24A. The chip terminal 24 contains, for example, at least one of Cu, Al, and Ti. The barrier layer 24B is, for example, a plating layer. The barrier layer 24B contains at least one of Au, Ni, and Pd. In an example, the barrier layer 24B is formed from a material containing Ni.

The mount portion 32 of each terminal 30 includes a barrier layer 36 formed in a region where the chip terminal 24 is connected. The region where the chip terminal 24 is connected may also be referred to as a region where the semiconductor chip 20 is mounted. In an example, the barrier layer 36 has a circular shape in plan view. The planar shape of the barrier layer 36 may be changed. The barrier layer 36 contains, for example, at least one of Ni and Ti.

The barrier layer 24B of each chip terminal 24 is bonded to the barrier layer 36 of a corresponding mount portion 32 by a conductive bonding material SD. This mounts the semiconductor chip 20 on the mount portions 32. The barrier layer 36 maintains the wettability of the conductive bonding material SD. In this manner, the chip terminals 24 are electrically connected to the mount portions 32 of the terminals 30. The conductive bonding material SD may be, for example, silver (Ag) paste or solder paste.

### Groove in Terminal

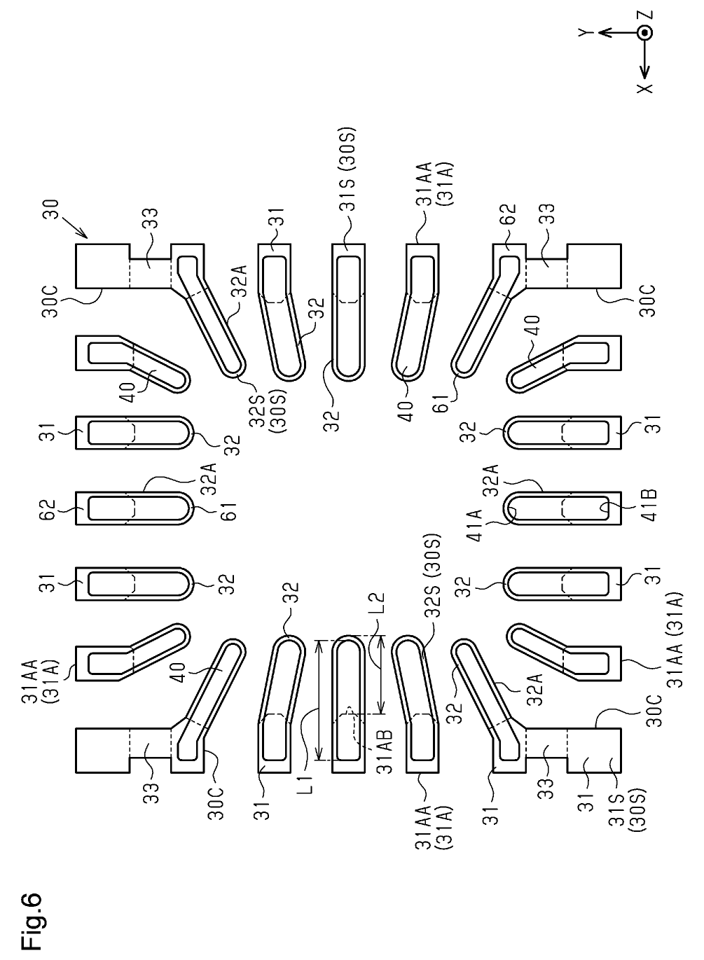

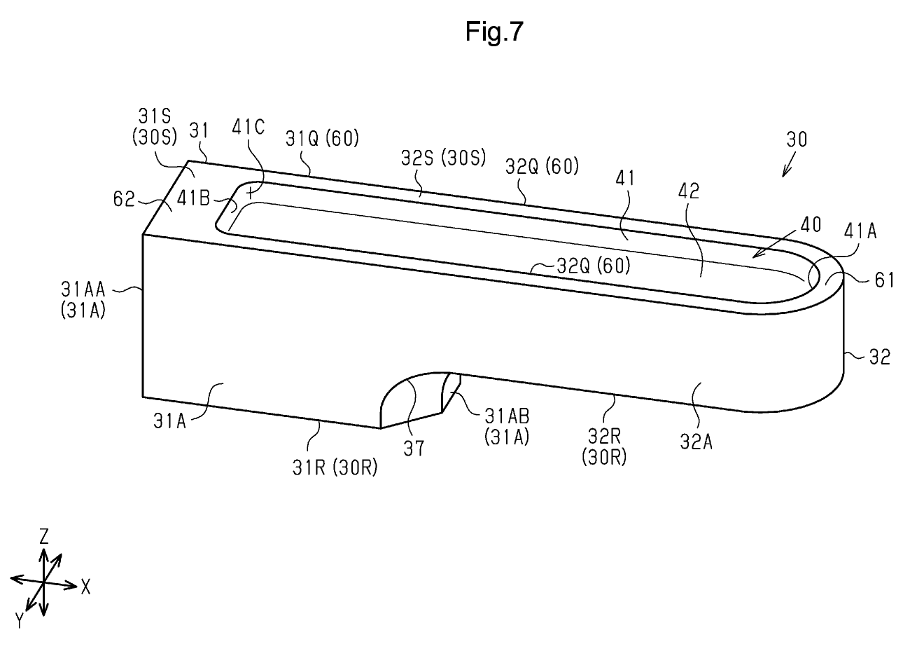

As shown in FIG. 4, each terminal 30 includes a groove 40. The structure of the groove 40 of the terminal 30 will now be described with reference to FIGS. 4 to 7. FIG. 6 is a schematic plan view showing the structures of the terminals 30. FIG. 7 is a schematic perspective view showing the structure of one of the terminals 30.

As shown in FIGS. 4 to 7, the groove 40 is formed in at least the mount portion 32. The groove 40 is located between two opposite ends of the terminal 30 in a direction (hereafter, “the second direction”) which is orthogonal to both the first direction and the Z-direction. The groove 40 extends in the first direction in the mount portion 32. Accordingly, the first direction defines the lengthwise direction of the mount portion 32. The second direction defines the widthwise direction of the mount portion 32. The first direction also defines the lengthwise direction of the groove 40. The second direction also defines the widthwise direction of the groove 40.

As shown in FIGS. 4 and 5, the groove 40 is recessed from the terminal head surface 30S toward the terminal back surface 30R. More specifically, a portion of the groove 40 located in the mount portion 32 is recessed from the mount portion head surface 32S toward the mount portion back surface 32R. Another portion of the groove 40 located in the terminal portion 31 is recessed from the terminal portion head surface 31S toward the terminal portion back surface 31R. As shown in FIG. 4, a portion of the mount portion 32 in which the groove 40 is formed is less than 1/2 of the thickness of the terminal portion 31. That is, the mount portion 32 includes a part that is thinner than 1/2 of the thickness of the terminal portion 31. The thickness of the terminal portion 31 may be defined by the distance from the terminal portion head surface 31S to the terminal portion back surface 31R in the Z-direction.

Each terminal 30 includes a wall portion 60 formed by the groove 40, which is recessed from the terminal head surface 30S toward the terminal back surface 30R. The wall portion 60 is located at two sides of the terminal 30 in the second direction. The wall portion 60 extends in the first direction.

As viewed in the first direction, the mount portion 32 is U-shaped due to the groove 40 formed in the mount portion 32. Since the groove 40 is recessed from the mount portion head surface 32S toward the mount portion back surface 32R, the mount portion 32 includes a base portion 32P and a wall portion 32Q. The wall portion 32Q extends upward from the base portion 32P. In the first embodiment, the base portion 32P and the wall portion 32Q are integrally formed as an integrated structure. The wall portion 32Q extends in the first direction at two opposite ends of the mount portion 32 in the second direction. The wall portion 32Q defines part of the wall portion 60. The base portion 32P includes the mount portion back surface 32R. The wall portion 32Q includes the mount portion head surface 32S.

Since the groove 40 is recessed from the terminal portion head surface 31S toward the terminal portion back surface 31R, the terminal portion 31 includes a wall portion 31Q continuous with the wall portion 32Q of the mount portion 32 (refer to FIG. 7). The wall portion 31Q defines part of the wall portion 60. The wall portion 31Q includes the terminal portion head surface 31S. In the first embodiment, the wall portion 31Q and the wall portion 32Q are integrally formed as an integrated structure. That is, the wall portion 60 is formed by the wall portions 31Q and 32Q. The wall portion 60 includes the terminal head surface 30S.

As shown in FIG. 6, the groove 40 extends from the terminal portion 31 to a distal end part of the mount portion 32. In the first embodiment, the groove 40 is located closer to the terminal portion 31 than a distal edge of the mount portion 32 is. That is, the groove 40 formed in the mount portion 32 is not open in the first direction. Accordingly, as shown in FIG. 7, the mount portion 32 includes a distal end connecting wall 61 at the distal end part of the mount portion 32. The distal end connecting wall 61 connects the wall portion 32Q (wall portion 60) located at two sides of the mount portion 32 in the second direction. In plan view, the distal end connecting wall 61 has a semicircular shape that conforms to the distal end part of the mount portion 32. The distal end connecting wall 61 includes the mount portion head surface 32S.

The groove 40 extends over both the terminal portion 31 and the mount portion 32. The groove 40 is located closer to the mount portion 32 than one of two opposite ends of the terminal portion 31 located away from the mount portion 32 is in the first direction. In other words, in plan view, the groove 40 is located closer to the mount portion 32 than the exposed side surface 31AA of the terminal portion 31 is. That is, the groove 40 formed in the terminal portion 31 is not open in the first direction. Accordingly, as shown in FIG. 7, the terminal portion 31 includes a basal end connecting wall 62 connecting the wall portion 31Q (wall portion 60) located at two sides of the terminal portion 31 in the second direction. The basal end connecting wall 62 includes the terminal portion head surface 31S.

As shown in FIGS. 5 and 7, the groove 40 includes a side surface 41 and a bottom surface 42.

As shown in FIG. 7, the side surface 41 extends from the terminal head surface 30S toward the terminal back surface 30R. The side surface 41 extends in the first direction. The side surface 41 includes a distal end side surface 41A that defines the distal end of the groove 40 in the first direction. In plan view, the distal end side surface 41A has the same shape as, for example, the distal end surface of the mount portion 32. In an example, in plan view, the distal end side surface 41A has a semicircular shape. The side surface 41 includes a basal end side surface 41B that defines the basal end of the groove 40 in the first direction. For example, in plan view, the basal end side surface 41B extends in the second direction. A curved side surface 41C is formed between the basal end side surface 41B and the side surface 41, which extends in the first direction. The curved side surface 41C is curved in plan view. The side surface 41 defines the inner surface of the wall portion 60. The distal end side surface 41A defines the inner surface of the distal end connecting wall 61. The basal end side surface 41B defines the inner surface of the basal end connecting wall 62.

As shown in FIG. 5, the bottom surface 42 is, for example, flat and orthogonal to the Z-direction. The bottom surface 42 defines a surface of the base portion 32P that faces away from the mount portion back surface 32R. The bottom surface 42 includes a region where the chip terminal 24 of the semiconductor chip 20 is mounted on the mount portion 32. The barrier layer 36 is formed on the bottom surface 42. In other words, the barrier layer 36 is located closer to the mount portion back surface 32R than the mount portion head surface 32S is in the Z-direction. The barrier layer 36 is thinner than a depth H1 of the groove 40. The conductive bonding material SD is disposed in the groove 40. In other words, the chip terminal 24 is bonded to the mount portion 32 in the groove 40. That is, the chip terminal 24 is bonded to the bottom surface 42 in the groove 40.

The depth H1 of the groove 40 is greater than or equal to a thickness T1 of the conductive bonding material SD. The distal end surface of the chip terminal 24, that is, a surface of the barrier layer 24B contacting the conductive bonding material SD, may be located at the same position as the mount portion head surface 32S in the Z-direction or may be located closer to the mount portion back surface 32R than the mount portion head surface 32S is. That is, when the depth H1 of the groove 40 is equal to a sum of the thickness T1 of the conductive bonding material SD and the thickness of the barrier layer 36, the distal end surface of the chip terminal 24 is located at the same position as the mount portion head surface 32S in the Z-direction. When the depth H1 of the groove 40 is less than the sum of the thickness T1 of the conductive bonding material SD and the thickness of the barrier layer 36, the distal end surface of the chip terminal 24 is located closer to the encapsulation head surface 50S (refer to FIG. 4) than the mount portion head surface 32S is in the Z-direction. When the depth H1 of the groove 40 is greater than the sum of the thickness T1 of the conductive bonding material SD and the thickness of the barrier layer 36, the distal end surface of the chip terminal 24 is located closer to the mount portion back surface 32R than the mount portion head surface 32S is in the Z-direction. In an example, the depth H1 of the groove 40 is 10 μm or less. The depth H1 of the groove 40 may be defined by the distance from the terminal head surface 30S to the bottom surface 42 of the groove 40 in the Z-direction. Therefore, the depth H1 of the groove 40 means the height of the wall portion 60.

As shown in FIG. 5, the groove 40 includes a curved surface 43 located between the side surface 41 and the bottom surface 42. Accordingly, the width of the bottom surface 42 is less than the distance between opposing part of the side surface 41 in the second direction. The width of the bottom surface 42 may be defined by the dimension of the bottom surface 42 in the second direction. The width of the bottom surface 42 is greater than the diameter of the chip terminal 24. Therefore, a width W1 of the groove 40 is greater than the diameter of the chip terminal 24 of the semiconductor chip 20. The width W1 of the groove 40 may be defined by, for example, the distance between opposing parts of the side surface 41 in the second direction. The width W1 of the groove 40 is greater than 1/2 of a width W2 of the mount portion 32. In an example, the width W1 of the groove 40 is approximately 2/3 of the width W2 of the mount portion 32.

As shown in FIG. 6, a length L1 of the groove 40 may be greater than or equal to a length L2 of the mount portion 32. In an example, the length L1 of the groove 40 is greater than the length L2 of the mount portion 32. In plan view, the length L2 of the mount portion 32 may be defined by the distance from the inner side surface 31AB of the terminal portion 31 to the distal end surface of the mount portion 32 in the direction in which the mount portion 32 extends.

### Method for Manufacturing Semiconductor Device

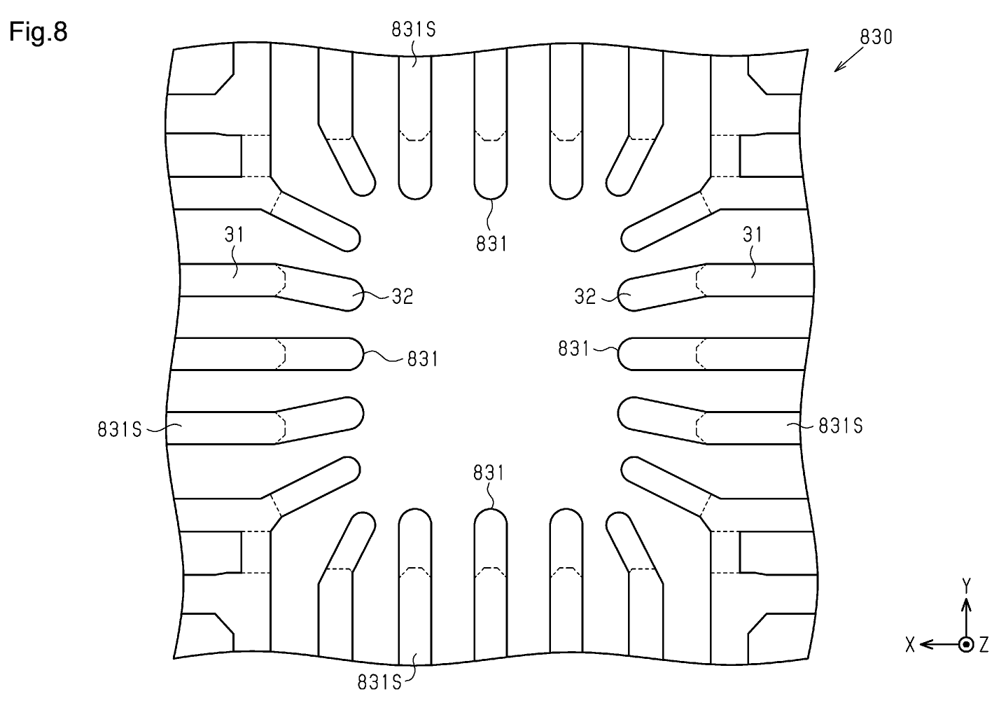

An example of a method for manufacturing the semiconductor device 10 in accordance with the first embodiment will now be described with reference to FIGS. 8 to 14.

The method for manufacturing the semiconductor device 10 mainly includes a step of preparing the terminals 30, a step of mounting the semiconductor chip 20 on the terminals 30, a step of cleaning the terminals 30, a step of forming the encapsulation resin 50, and a step of singulation.

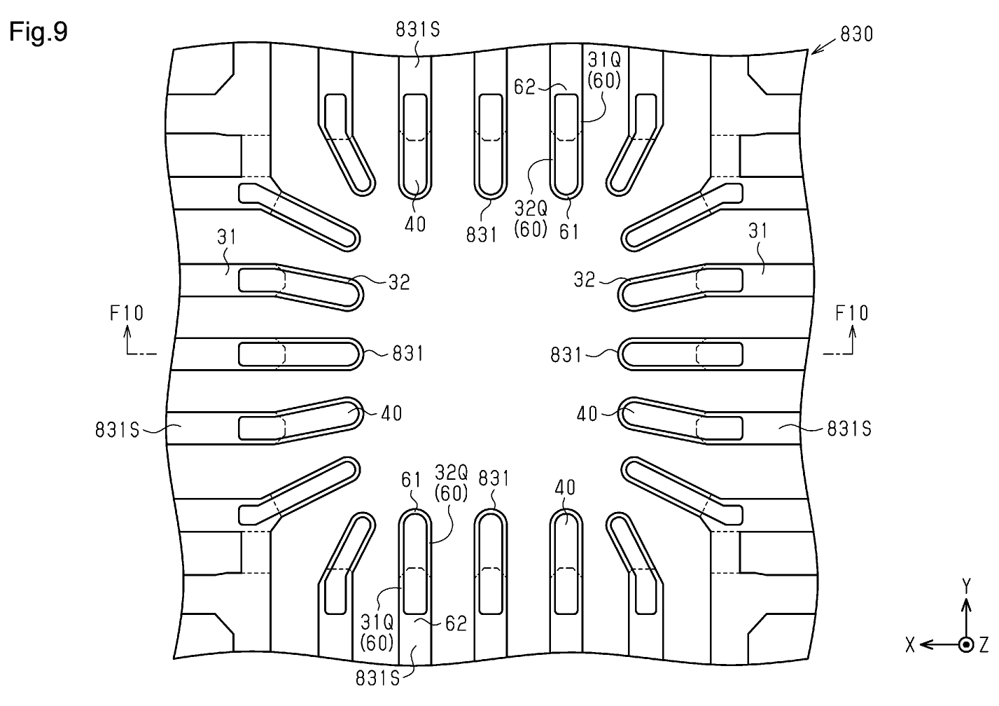

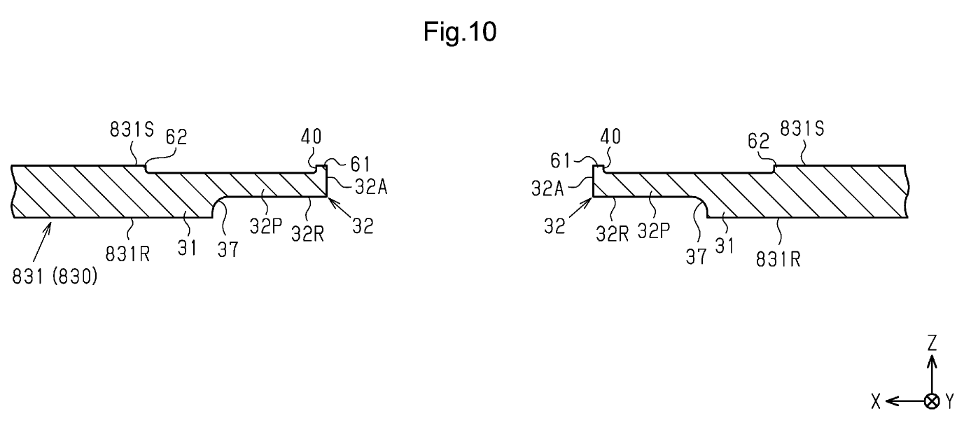

FIGS. 8 to 10 illustrate an example of the step of preparing the terminals 30. FIGS. 8 and 9 are schematic plan views showing the structure of part of a lead frame 830. FIG. 10 shows a cross-sectional structure taken along line F10-F10 shown in FIG. 9.

As shown in FIG. 8, in the step of preparing the terminals 30, the metal lead frame 830 is prepared. In this step, a flat metal plate is first prepared. The metal plate is used to form the terminals 30. Then, a head surface resist is formed on the head surface of the metal plate, and a back surface resist is formed on the back surface of the metal plate. The head surface resist covers portions of the head surface of the metal plate that correspond to the terminal portions 31 and the mount portions 32 of the terminals 30. Therefore, the head surface resist exposes portions of the head surface of the metal plate that do not correspond to the terminals 30. The back surface resist covers portions of the back surface of the metal plate that correspond to the terminal portions 31 of the terminals 30. Therefore, the back surface resist exposes portions of the back surface of the metal plate that do not correspond to the terminals 30, and portions of the back surface of the metal plate that correspond to the mount portion 32. For example, half-etching is performed to partially remove the portions of the back surface of the metal plate that do not correspond to the terminals 30 and the portions of the back surface that correspond to the mount portion 32 in the Z-direction. Further, for example, half-etching is performed to remove the portions of the head surface of the metal plate that do not correspond to the terminals 30. Then, the head surface resist and the back surface resist are removed. The lead frame 830 is manufactured by the above-described procedure.

The lead frame 830 has a flat plate shape and has a thickness-wise direction parallel to the Z-direction. The lead frame 830 is formed from a material containing, for example, Cu. The lead frame 830 includes lead portions 831 corresponding to the terminals 30, and a frame portion (not shown) supporting the lead portions 831. The lead frame 830 is formed by, for example, etching a metal plate containing Cu. The lead portions 831 extend in directions (first direction) orthogonal to the Z-direction. The lead portions 831 each include a lead head surface 831S and a lead back surface 831R, facing away from each other in the Z-direction (refer to FIGS. 9 and 10). The step of preparing the terminals 30 includes forming the terminal portions 31 and the mount portions 32 by selectively etching the lead portions 831. As a result, the lead portions 831 include the terminal portions 31 and the mount portions 32 of the terminals 30. In FIG. 8, in order to facilitate understanding, a broken line indicates the boundary of the terminal portion 31 and the mount portion 32.

As shown in FIG. 9, the step of preparing the terminals 30 includes a step of forming the groove 40 in each lead portion 831 by etching the lead portion 831. In the step of preparing the terminals 30 in accordance with the first embodiment, the groove 40 is formed after forming the mount portion 32.

The groove 40 is formed in a region of the lead portion 831 that corresponds to at least the mount portion 32. In other words, the step of preparing the terminals 30 includes a step of forming the groove 40 by etching a region of the lead frame 830 that corresponds to at least the mount portion 32. In an example, a resist covers a portion of the lead frame 830 that corresponds to the terminal portion head surface 31S of the terminal portion 31 and the mount portion head surface 32S of the mount portion 32, except for a region in which the groove 40 is to be formed. Then, the region exposed from the resist is etched. In an example, the resist covers a region of the lead portion 831 that corresponds to two opposite ends of the mount portion 32 in the second direction orthogonal to both the first direction and the Z-direction, and a region of the lead portion 831 that corresponds to two opposite ends of the terminal portion 31 in the second direction. As a result, the groove 40 is located between two opposite ends, in the second direction, of a region of the lead portion 831 that corresponds to the terminal 30. The second direction defines the widthwise direction of the lead portion 831. The groove 40 extends in the first direction. In the first embodiment, the groove 40 is formed in a portion of the lead portion 831 that corresponds to both the terminal portion 31 and the mount portion 32.

As shown in FIG. 10, the groove 40 is formed by partially etching at least the mount portion 32 from the lead head surface 831S. That is, the step of preparing the terminals 30 includes forming the grooves 40 by partially etching at least the mount portions 32 from the lead head surface 831S. In the first embodiment, each groove 40 is formed by partially etching both the terminal portion 31 and the mount portion 32 from the lead head surface 831S. That is, forming the groove 40 includes forming the groove 40 that is recessed from the mount portion head surface 32S, which serves as a region of the lead frame 830 corresponding to the mount portion 32, toward the mount portion back surface 32R. Also, forming the groove 40 includes forming the groove 40 that is recessed from the terminal portion head surface 31S, which serves as a region of the lead frame 830 corresponding to the terminal portion 31, toward the terminal portion back surface 31R.

As shown in FIGS. 9 and 10, when the groove 40 is formed, the mount portion 32 includes the base portion 32P, the wall portion 32Q (wall portion 60) extending upward from the base portion 32P, and the distal end connecting wall 61. Further, a portion of the lead portion 831 that corresponds to the terminal portion 31 includes the basal end connecting wall 62. The wall portion 32Q is formed at two opposite ends of the mount portion 32 in the second direction, such that the mount portion 32 is U-shaped as viewed in the first direction. The wall portion 32Q extends in the first direction.

The groove 40 also forms the wall portion 31Q in a region of the lead portion 831 that corresponds to the terminal portion 31. The wall portion 31Q is formed at two opposite ends of the terminal portion 31 in the second direction. The wall portion 31Q extends in the first direction. In this manner, the present step forms the wall portion 60 including the wall portion 31Q and the wall portion 32Q. The wall portion 60 extends in the first direction.

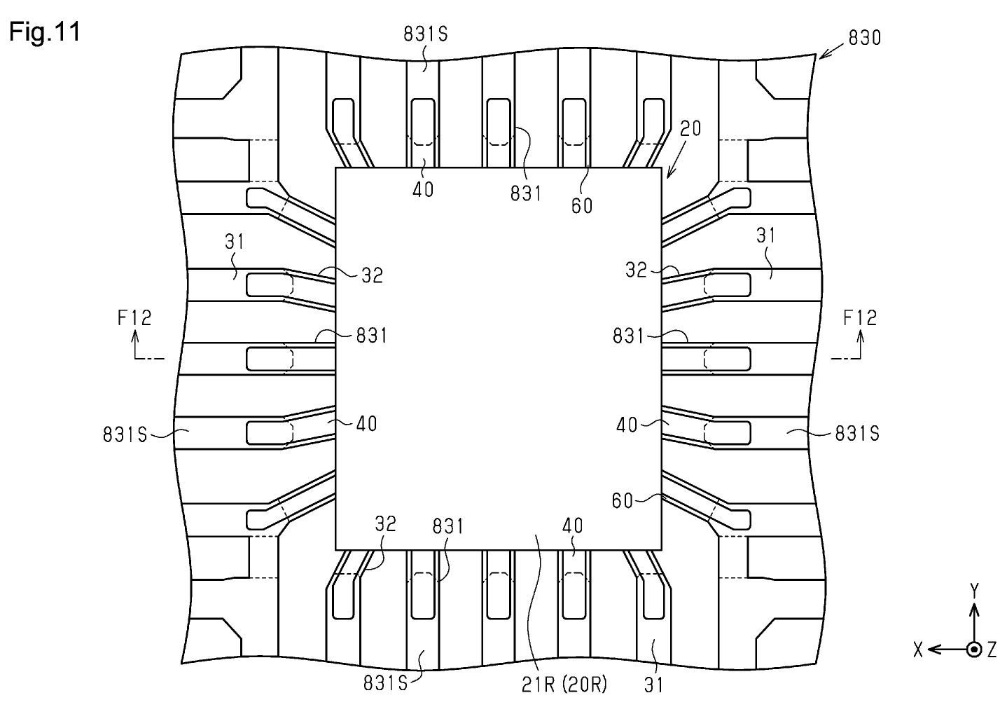

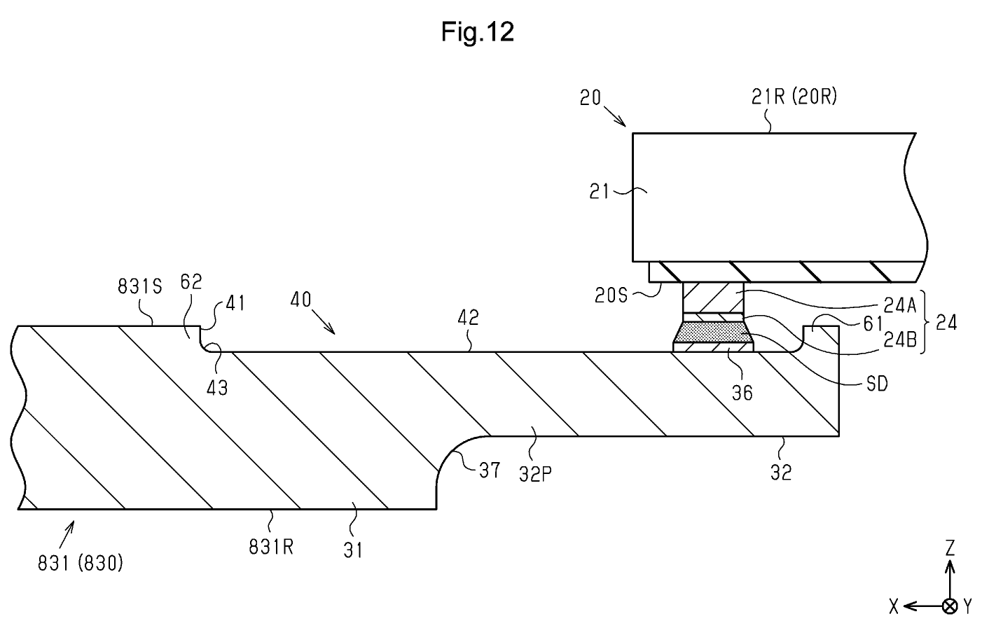

FIGS. 11 and 12 illustrate an example of a step of mounting the semiconductor chip 20 on the terminals 30. FIG. 11 is a schematic plan view showing the structure of the semiconductor chip 20 and part of the lead frame 830. FIG. 12 is a schematic cross-sectional view taken along line F12-F12 shown in FIG. 11, showing the structure of the part of the lead frame 830 and the semiconductor chip 20.

In the step of mounting the semiconductor chip 20 on the terminals 30, the chip terminals 24 of the semiconductor chip 20 are arranged on the terminals 30. More specifically, first, the conductive bonding material SD is applied to each chip terminal 24 of the semiconductor chip 20. Next, the chip terminal 24 of the semiconductor chip 20 is disposed on the barrier layer 36 formed on the bottom surface 42 of the groove 40 in the mount portion 32 of a corresponding terminal 30. Subsequently, the conductive bonding material SD is melted and then solidified by, for example, reflow soldering. As a result, the chip terminal 24 is bonded to the terminal 30. This electrically connects the chip terminals 24 to the terminals 30.

In the step of mounting the semiconductor chip 20 on the terminals 30, a layer of the conductive bonding material SD may be formed on the barrier layer 36, and then the chip terminal 24 of the semiconductor chip 20 may be arranged on the conductive bonding material SD. Alternatively, in the step of mounting the semiconductor chip 20 on the terminals 30, a layer of the conductive bonding material SD may be formed on both the barrier layer 36 and the chip terminal 24, and then the semiconductor chip 20 may be disposed on the mount portion 32 so that the conductive bonding material SD applied to the barrier layer 36 is bonded to the conductive bonding material SD applied to the chip terminal 24.

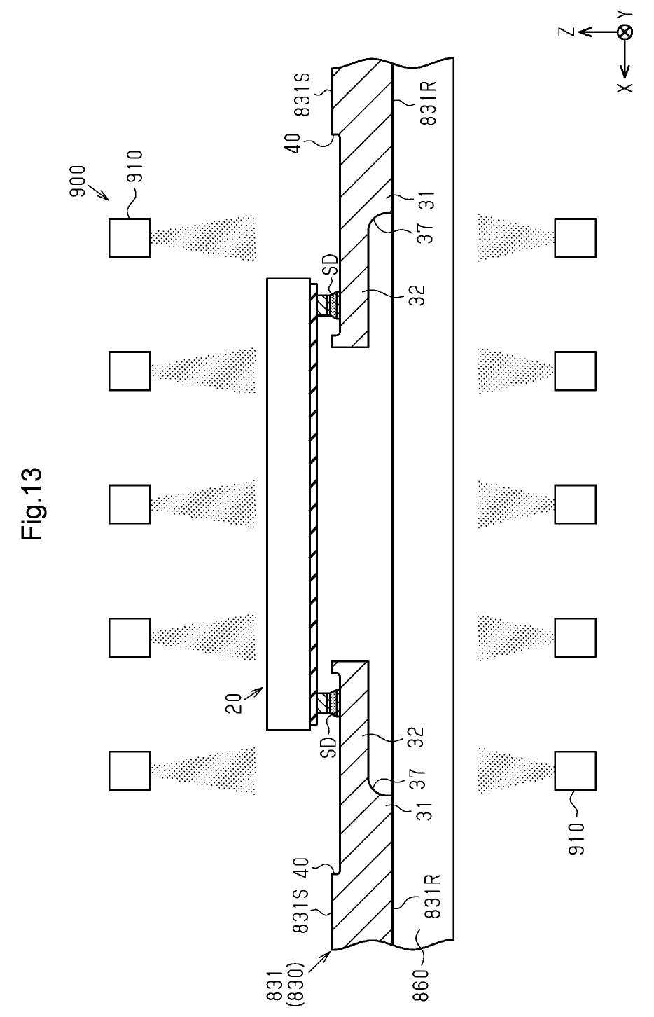

FIG. 13 illustrates an example of a step of cleaning the terminals 30 and the semiconductor chip 20. FIG. 13 shows a schematic cross-sectional view in which the semiconductor chip 20 is mounted on the terminals 30.

As shown in FIG. 13, the lead frame 830, on which the semiconductor chip 20 is mounted, is loaded into, for example, a cleaning device 900 in a state in which the lead frame 830 is supported by a support board 860. The cleaning device 900 includes spray nozzles 910. The spray nozzles 910 spray pure water and chemical agent onto the semiconductor chip 20 and the lead frame 830. This cleans and removes foreign matter and contaminants from the semiconductor chip 20 and the lead frame 830. In this manner, the step of cleaning the terminals 30 and the semiconductor chip 20 is performed after forming the groove 40. Also, this step is performed after the step of mounting the semiconductor chip 20.

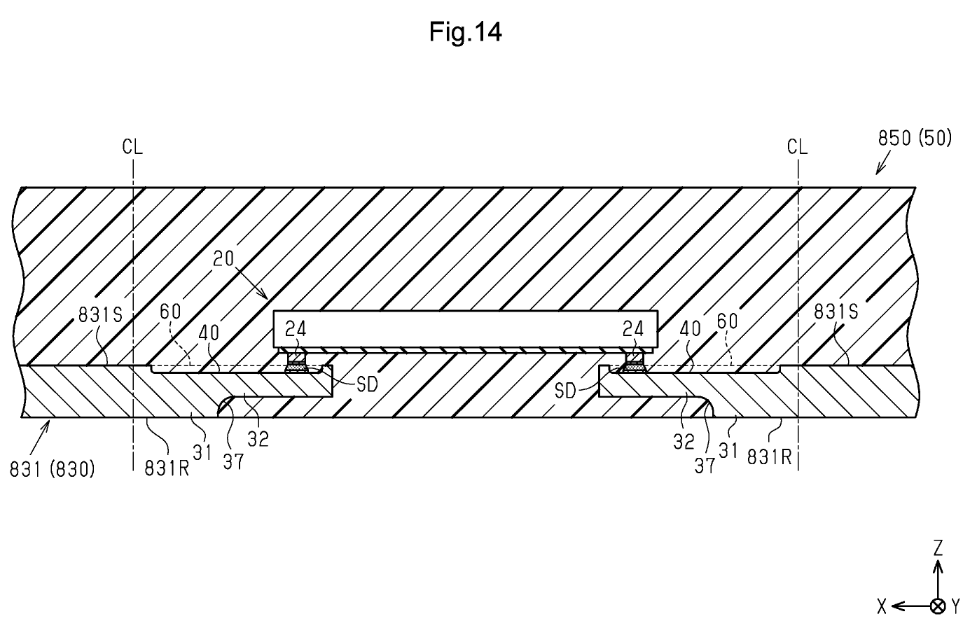

FIG. 14 illustrates the step of forming the encapsulation resin 50 and the step of singulation. FIG. 14 is a schematic cross-sectional view showing the structure of the semiconductor chip 20, the encapsulation resin 50, and part of the lead frame 830.

In the step of forming the encapsulation resin 50, a resin layer 850 is formed by, for example, transfer molding to cover the semiconductor chip 20 and the lead frame 830. The resin layer 850 includes multiple pieces of the encapsulation resin 50.

In the singulating step, the resin layer 850 and the lead frame 830 are cut along cutting lines CL shown in FIG. 14 by, for example, dicing. This obtains multiple pieces of the encapsulation resin 50 and multiple pieces of the terminals 30. The terminal portion side surfaces 31A (refer to FIG. 4) of the terminal portions 31 of the terminals 30 are exposed from the four encapsulation side surfaces 50A (refer to FIG. 2) of the encapsulation resin 50.

Although not shown in the drawings, the method for manufacturing the semiconductor device 10 includes a step of forming the back surface plating layer 34 and the side surface plating layer 35 (refer to FIG. 4). The back surface plating layer 34 and the side surface plating layer 35 are both formed by, for example, electroless plating. As a result, the back surface plating layer 34 is formed on the terminal portion back surface 31R of the terminal 30 exposed from the encapsulation resin 50, and the side surface plating layer 35 is formed on the exposed side surface 31AA. The semiconductor device 10 is manufactured by the above-described procedure.

### Operation of the First Embodiment

The operation of the semiconductor device 10 in accordance with the first embodiment will now be described. A comparative semiconductor device includes terminals 30 that do not include the groove 40 of the semiconductor device 10 in accordance with the first embodiment.

The mount portion of each terminal of the comparative semiconductor device is flat. Accordingly, in the step of cleaning the terminals and the semiconductor chip, the sprayed pure water and chemical agent may vibrate the mount portion in the Z-direction. This may apply force to the conductive bonding material between the mount portion and the semiconductor chip, such that the conductive bonding material SD may crack or separate. As a result, the electrical connection may become unstable between the mount portion and the chip terminal of the semiconductor chip.

In this respect, in the semiconductor device 10 of the first embodiment, the groove 40 is formed in at least the mount portion 32 of each terminal 30. Accordingly, the mount portion 32 includes the base portion 32P, and the wall portion 32Q (wall portion 60) extending upward from two sides of the base portion 32P in the second direction. That is, the mount portion 32 is U-shaped as viewed in the first direction. With the semiconductor device 10 of the first embodiment, the mount portion 32 resists bending as compared to a structure that does not include the groove 40, that is, a structure that does not include the wall portion 32Q (wall portion 60). Therefore, in the step of cleaning the terminals 30 and the semiconductor chip 20, the mount portion 32 will not be vibrated in the Z-direction by the sprayed pure water and the chemical agent. This avoids cracking or separation of the conductive bonding material SD caused by force applied to the conductive bonding material SD between the mount portion 32 and the chip terminals 24 of the semiconductor chip 20. As a result, the electrical connection is stable between the mount portion 32 and the chip terminal 24.

### Advantages of the First Embodiment

The semiconductor device 10 in accordance with the first embodiment has the following advantages.

(1-1) The semiconductor device 10 includes the terminals 30, the semiconductor chip 20, and the encapsulation resin 50. The semiconductor chip 20 is mounted on the terminals 30. The encapsulation resin 50 encapsulates the terminals 30 and the semiconductor chip 20. The terminals 30 each include the terminal head surface 30S, and the terminal back surface 30R facing away from the terminal head surface 30S. The terminals 30 each include the terminal portion 31, the mount portion 32, the groove 40, and the wall portion 60. The terminal portion 31 includes the terminal portion back surface 31R exposed from the encapsulation resin 50. The terminal portion back surface 31R is part of the terminal back surface 30R. The mount portion 32 extends from the terminal portion 31 in the first direction orthogonal to the Z-direction, which is the thickness-wise direction of the terminal 30. The semiconductor chip 20 is mounted on the mount portion 32. The groove 40 is formed in at least the mount portion 32. The groove 40 extends in the first direction. The wall portion 60 extends in the first direction. The wall portion 60 is located at two opposite ends of the groove 40 in the second direction orthogonal to both the Z-direction and the first direction.

With this structure, the wall portion 60 is formed on the mount portion 32, so that the mount portion 32 resists bending as compared to a mount portion without the wall portion 60. Therefore, in the step of cleaning the terminals 30 and the semiconductor chip 20, the mount portion 32 will not be vibrated in the Z-direction by the sprayed pure water and the chemical agent. This avoids a situation in which vibration of the mount portion 32 applies force to the conductive bonding material SD, thereby stabilizing the electrical connection between the mount portion 32 and the semiconductor chip 20.

(1-2) The groove 40 extends from the terminal portion 31 to the distal end part of the mount portion 32.

With this structure, the groove 40 is formed in a relatively large region of the mount portion 32 in the first direction, in other words, the wall portion 60 is disposed in a relatively large region of the mount portion 32 in the first direction. This allows the mount portion 32 to resist bending. Therefore, in the step of cleaning the terminals 30 and the semiconductor chip 20, the mount portion 32 will not be vibrated in the Z-direction by the sprayed pure water and the chemical agent.

(1-3) The groove 40 extends over both the terminal portion 31 and the mount portion 32.

In other words, the wall portion 60 of this structure extends over both the terminal portion 31 and the mount portion 32. Accordingly, the mount portion 32 resists bending at an end part of the mount portion 32 located relatively close to the terminal portion 31. Therefore, in the step of cleaning the terminals 30 and the semiconductor chip 20, the mount portion 32 will not be vibrated in the Z-direction by the sprayed pure water and the chemical agent.

(1-4) The groove 40 includes the side surface 41, the bottom surface 42, and the curved surface 43 located between the side surface 41 and the bottom surface 42. The curved surface 43 is curved toward the inner side of the mount portion 32 as the curved surface 43 extends toward the bottom surface 42.

With this structure, stress will not concentrate in a portion connecting the side surface 41 and the bottom surface 42 as compared to a structure that does not include the curved surface 43 such that, for example, the side surface 41 is orthogonal to the bottom surface 42. This avoids cracking or deformation of a portion of the mount portion 32 that defines the side surface 41 of the groove 40. In addition, the above described structure improves adhesion between the encapsulation resin 50 and the portion connecting the side surfaces 41 and the bottom surface 42 as compared to a structure in which, for example, the side surfaces 41 is orthogonally connected to the bottom surface 42. This avoids delamination of the encapsulation resin 50 from the mount portion 32.

(1-5) The groove 40 has the depth H1 of 10 μm or less.

With this structure, a portion of the mount portion 32 in which the groove 40 is formed is not overly thin. This maintains a sufficient strength of the mount portion 32, so that the mount portion 32 resists bending.

(1-6) The length of the mount portion 32 in the first direction is greater than the length of the terminal portion 31 in the first direction.

This structure obtains a fan-out package structure while reducing the size of the semiconductor device 10 in a direction orthogonal to the Z-direction. When the mount portion is relatively long in the first direction, the mount portion may be prone to bending. However, the wall portion 60 disposed on the mount portion 32 allows the mount portion 32 to resist bending even when the mount portion 32 is relatively long in the first direction.

(1-7) The terminal portion 31 includes the exposed side surface 31AA exposed from the encapsulation side surface 50A of the encapsulation resin 50. The side surface plating layer 35, which serves as a side surface conductive film, is formed on the exposed side surface 31AA.

With this structure, when mounting the semiconductor device 10 on a circuit substrate using a conductive bonding material, such as solder paste, the conductive bonding material may adhere to the side surface plating layer 35. This allows for visual recognition of the mounting state of the semiconductor device 10 on the circuit substrate.

(1-8) The method for manufacturing the semiconductor device 10 includes preparing the terminals 30, mounting the semiconductor chip 20 on the terminals 30, and forming the encapsulation resin 50 to encapsulate the terminals 30 and the semiconductor chip 20. The terminals 30 each include the terminal head surface 30S, and the terminal back surface 30R facing away from the terminal head surface 30S. The preparing the terminals 30 includes forming the terminal portion 31 and the mount portion 32. The mount portion 32 extends from the terminal portion 31 in the first direction orthogonal to the Z-direction, which is the thickness-wise direction of the terminals 30. The semiconductor chip 20 is configured to receive the mount portion 32. The preparing the terminals 30 further includes forming the groove 40 by etching at least the mount portion 32. The groove 40 extends in the first direction in the mount portion 32. The wall portion 60 is located at two opposite ends of the groove 40 in the second direction orthogonal to both the Z-direction and the first direction. The wall portion 60 extends in the first direction.

With this structure, the wall portion 60 is formed on the mount portion 32, so that the mount portion 32 resists bending as compared to a mount portion without the wall portion 60. This avoids a situation in which an external force applied to the mount portion 32 is transferred to the conductive bonding material SD, thereby stabilizing the electrical connection between the mount portion 32 and the semiconductor chip 20.

(1-9) The method for manufacturing the semiconductor device 10 further includes cleaning the terminals 30 after forming the groove 40.

With this structure, the groove 40 is formed in the mount portion 32, in other words, the wall portion 60 is disposed on the mount portion 32. Therefore, in the step of cleaning the terminals 30, the mount portion 32 will not be vibrated in the Z-direction by the sprayed pure water and the chemical agent. This avoids a situation in which vibration of the mount portion 32 applies force to the conductive bonding material SD, thereby stabilizing the electrical connection between the mount portion 32 and the semiconductor chip 20.

### Second Embodiment

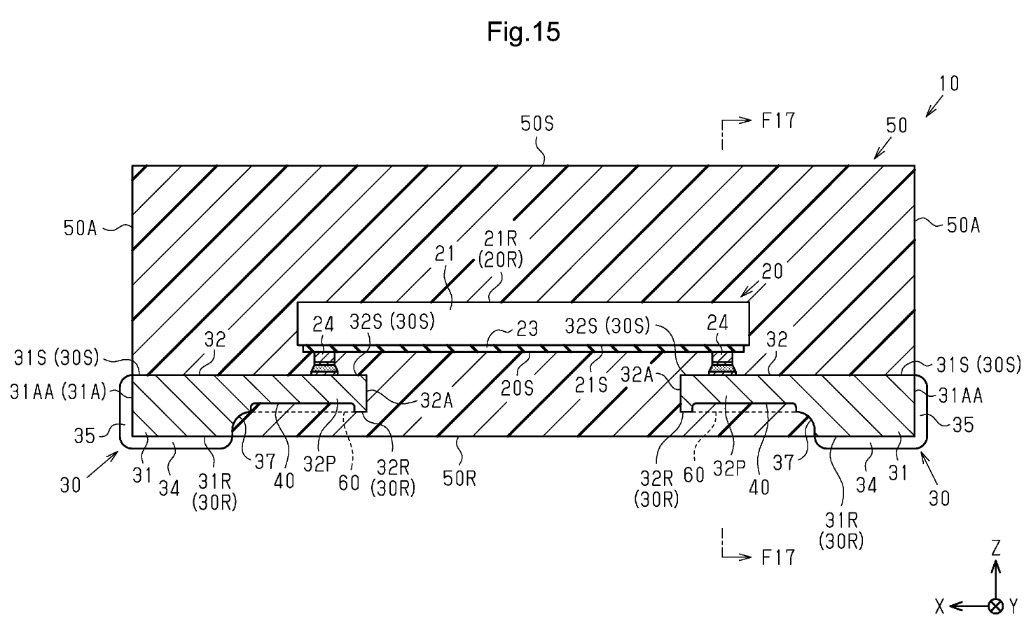

A semiconductor device 10 in accordance with a second embodiment will now be described with reference to FIGS. 15 to 17. The semiconductor device 10 of the second embodiment mainly differs from the semiconductor device 10 of the first embodiment in the structure of the terminal 30, particularly, the location of the groove 40. The description hereafter will focus on the differences from the semiconductor device 10 of the first embodiment. Same reference characters are given to those components that are the same as the corresponding components of the semiconductor device 10 of the first embodiment, and such components will not be described in detail.

### Structure of Semiconductor Device

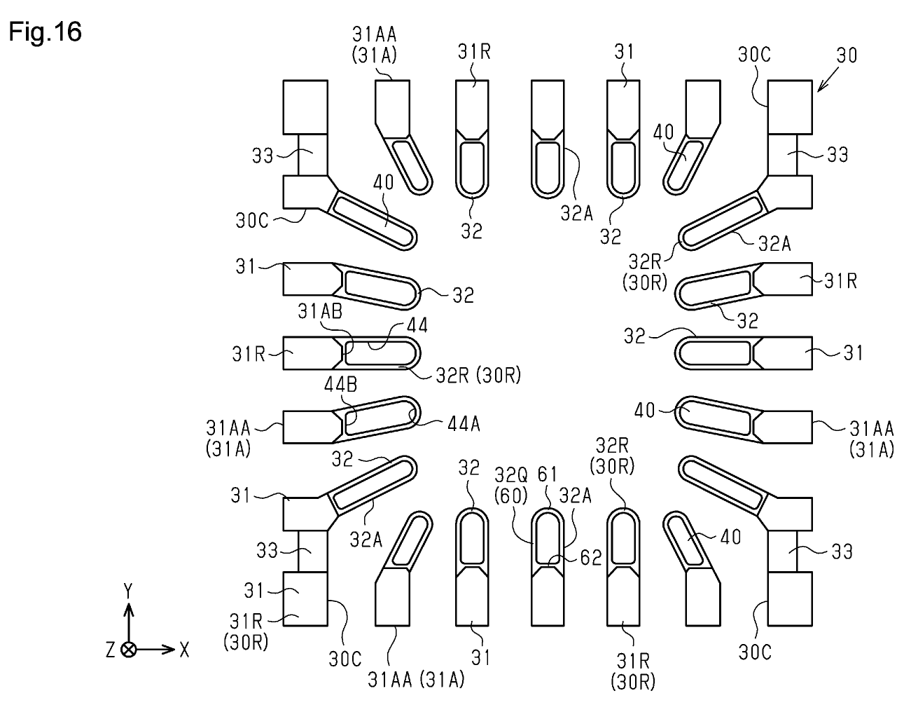

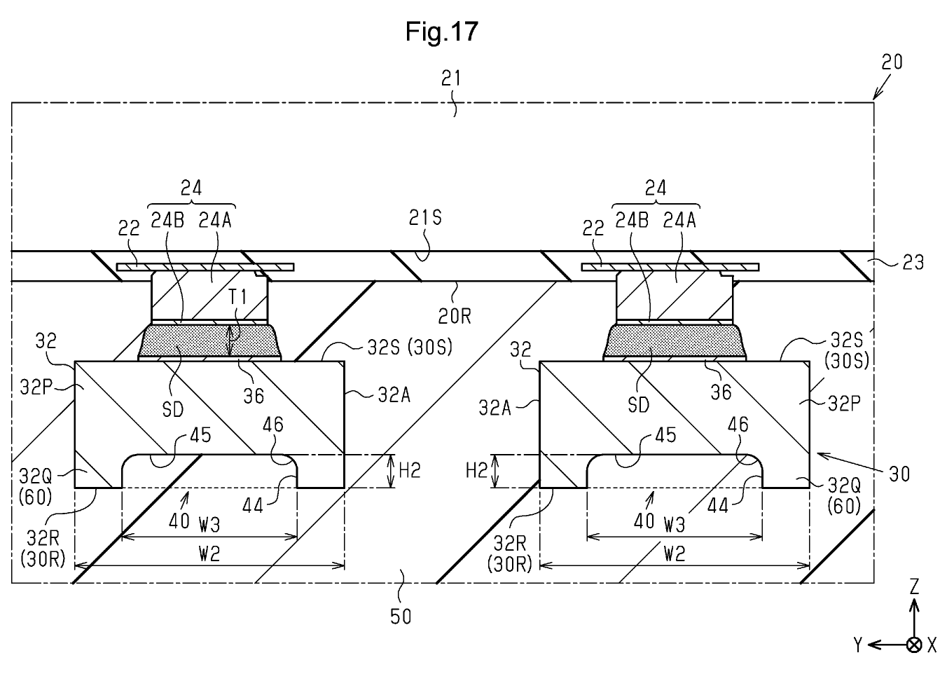

FIG. 15 is a schematic cross-sectional view showing the structure of the semiconductor device 10 in accordance with the second embodiment. The cross section of FIG. 15 is taken at the same position as that of FIG. 4. FIG. 16 is a schematic back view of the terminals 30. FIG. 17 is a schematic cross-sectional view taken along line F17-F17 shown in FIG. 15, showing the structure of part of the semiconductor device 10 in accordance with the second embodiment.

As shown in FIG. 15, in the second embodiment, the groove 40 is formed in the mount portion back surface 32R of the mount portion 32. The groove 40 is recessed from the mount portion back surface 32R toward the terminal head surface 30S (mount portion head surface 32S). A portion of the mount portion 32 in which the groove 40 is formed is thinner than 1/2 of the thickness of the terminal portion 31. That is, the mount portion 32 includes a part that is thinner than 1/2 of the thickness of the terminal portion 31.

In the second embodiment, the groove 40 is not formed in the terminal portion 31. That is, the groove 40 is formed in only the mount portion 32. The groove 40 is located between two opposite ends of the mount portion 32 in the second direction, which is orthogonal to both the first direction and the Z-direction. The groove 40 extends in the first direction in the mount portion 32.

As shown in FIG. 17, the terminals 30 each include the wall portion 60 formed by the groove 40, which is recessed from the terminal back surface 30R toward the terminal head surface 30S. The wall portion 60 is located at two sides of the terminal 30 in the second direction. The wall portion 60 extends in the first direction.

As viewed in the first direction, the mount portion 32 is U-shaped due to the groove 40 formed in the mount portion 32. The groove 40 is open toward the encapsulation back surface 50R. Since the groove 40 is recessed from the mount portion back surface 32R toward the mount portion head surface 32S, the mount portion 32 includes the base portion 32P, and the wall portion 32Q extending downward from the base portion 32P. In the second embodiment, the base portion 32P and the wall portion 32Q are integrally formed as an integrated structure. The wall portion 32Q extends in the first direction at two opposite ends of the mount portion 32 in the second direction. The wall portion 32Q defines part of the wall portion 60. The base portion 32P includes the mount portion head surface 32S. The wall portion 32Q includes the mount portion back surface 32R. In the second embodiment, the wall portion 60 is defined by the wall portion 32Q.

In the second embodiment, the groove 40 is not formed in the mount portion head surface 32S of the mount portion 32. In other words, in the second embodiment, the mount portion head surface 32S is flat and orthogonal to the Z-direction. The semiconductor chip 20 is mounted on the mount portion head surface 32S. More specifically, the barrier layer 36 is formed in a region of the mount portion head surface 32S where the chip terminal 24 of the semiconductor chip 20 is to be located (region where semiconductor chip 20 is to be mounted). The chip terminal 24 and the barrier layer 36 are bonded by the conductive bonding material SD.

As shown in FIG. 16, each terminal 30 includes the groove 40. The groove 40 is located closer to the terminal portion 31 than the distal edge of the mount portion 32 is. That is, the groove 40 of the second embodiment is not open in the first direction, which is the direction in which the mount portion 32 extends. Accordingly, the mount portion 32 includes the distal end connecting wall 61 at the distal end part of the mount portion 32. The distal end connecting wall 61 connects the wall portion 32Q (wall portion 60) located at two sides of the mount portion 32 in the second direction. In plan view, the distal end connecting wall 61 has a semicircular shape that conforms to the distal end part of the mount portion 32. The distal end connecting wall 61 includes the mount portion back surface 32R. Further, the mount portion 32 includes the basal end connecting wall 62 at the basal end part of the mount portion 32. The basal end connecting wall 62 connects the wall portion 32Q (wall portion 60) located at two sides of the mount portion 32 in the second direction. The basal end connecting wall 62 includes the mount portion back surface 32R.

As shown in FIG. 17, the groove 40 includes a side surface 44 and a bottom surface 45.

As shown in FIG. 16, the side surface 44 extends from the mount portion back surface 32R toward the mount portion head surface 32S. The side surface 44 extends in the first direction. The side surface 44 includes a distal end side surface 44A that defines the distal end of the groove 40 in the first direction. In plan view, the distal end side surface 44A has the same shape as, for example, the distal end surface of the mount portion 32. In an example, in plan view, the distal end side surface 44A has a semicircular shape. The side surface 44 includes a basal end side surface 44B that defines the basal end of the groove 40 in the first direction. In plan view, the basal end side surface 44B extends along, for example, the inner side surface 31AB of the terminal portion 31. A curved side surface is formed between the basal end side surface 44B and the side surface 44, which extends in the first direction. The curved side surface is curved in plan view. The bottom surface 45 is, for example, flat and orthogonal to the Z-direction. The side surface 44 defines the inner surface of the wall portion 60. The distal end side surface 44A defines the inner surface of the distal end connecting wall 61. The basal end side surface 44B defines the inner surface of the basal end connecting wall 62.

As shown in FIG. 17, a depth H2 of the groove 40 may be changed in a range in which the mount portion 32 resists bending compared to a mount portion without the groove 40. In an example, the depth H2 of the groove 40 is equal to the depth H1 of the groove 40 of the first embodiment (refer to FIG. 5). In other words, the height of the wall portion 60 of the second embodiment is equal to the height of the wall portion 60 of the first embodiment.

The groove 40 includes a curved surface 46 located between the side surface 44 and the bottom surface 45. Accordingly, the width of the bottom surface 45 is less than the distance between opposing parts of the side surface 44 in the second direction. The width of the bottom surface 45 may be defined by the dimension of the bottom surface 45 in the second direction. The width of the bottom surface 45 is greater than the diameter of the chip terminal 24. Therefore, a width W3 of the groove 40 is greater than the diameter of the chip terminal 24 of the semiconductor chip 20. The width W3 of the groove 40 may be defined by, for example, the distance between opposing parts of the side surface 44 in the second direction. The width W3 of the groove 40 is greater than 1/2 of the width W2 of the mount portion 32. In an example, the width W3 of the groove 40 is approximately 2/3 of the width W2 of the mount portion 32.

The mount portion head surface 32S is, for example, flat and orthogonal to the Z-direction. The mount portion head surface 32S includes a region where the chip terminal 24 of the semiconductor chip 20 is mounted on the mount portion 32. The barrier layer 36 is formed on the mount portion head surface 32S. The barrier layer 36 and the chip terminal 24 are bonded by the conductive bonding material SD.

### Method for Manufacturing Semiconductor Device

An example of a method for manufacturing the semiconductor device 10 in accordance with the second embodiment will now be described. The method for manufacturing the semiconductor device 10 in accordance with the second embodiment differs from the method for manufacturing the semiconductor device 10 in accordance with the first embodiment in the position of the mount portion 32 where the groove 40 is formed. More specifically, in the method for manufacturing the semiconductor device 10 of the second embodiment, the step of preparing the terminals 30 includes a step of forming the groove 40 in the mount portion 32 by etching the mount portion 32. That is, the step of forming the groove 40 includes forming the groove 40 that is recessed from the mount portion back surface 32R, which serves as a region of the lead frame 830 corresponding to the mount portion 32, toward the mount portion head surface 32S. In an example, a resist covers a portion of the lead portion 831 that corresponds to the mount portion back surface 32R of the mount portion 32, except for a region in which the groove 40 is to be formed. In an example, the resist covers two opposite ends, in the second direction, of a region of the lead portion 831 that corresponds to the mount portion back surface 32R. Then, the region exposed from the resist is etched. This forms the groove 40 in the central part of the mount portion back surface 32R in the second direction. Accordingly, the mount portion 32 includes the base portion 32P, the wall portion 32Q (wall portion 60) extending downward from the base portion 32P, and the distal end connecting wall 61. Further, a portion of the lead portion 831 that corresponds to the terminal portion 31 includes the basal end connecting wall 62. The resist is then removed. The subsequent steps are the same as those of the method for manufacturing the semiconductor device 10 in accordance with the first embodiment.

### Advantages of the Second Embodiment

The semiconductor device 10 of the second embodiment has the following advantages.

(2-1) The semiconductor device 10 of the second embodiment has advantages (1-2), and (1-4) to (1-9) of the first embodiment.

(2-2) The mount portion 32 includes the mount portion back surface 32R that defines part of the terminal back surface 30R. The groove 40 is recessed from the mount portion back surface 32R toward the terminal head surface 30S. The mount portion 32 includes the wall portion 60 extending in the first direction. The wall portion 60 is located at two opposite ends of the groove 40 in the second direction orthogonal to both the Z-direction and the first direction. The wall portion 60 includes the mount portion back surface 32R.

With this structure, the wall portion 60 is formed on the mount portion 32, so that the mount portion 32 resists bending as compared to a mount portion without the wall portion 60. Therefore, in the step of cleaning the terminals 30 and the semiconductor chip 20, the mount portion 32 will not be vibrated in the Z-direction by the sprayed pure water and the chemical agent. This avoids a situation in which vibration of the mount portion 32 applies force to the conductive bonding material SD, thereby stabilizing the electrical connection between the mount portion 32 and the semiconductor chip 20.

### Third Embodiment

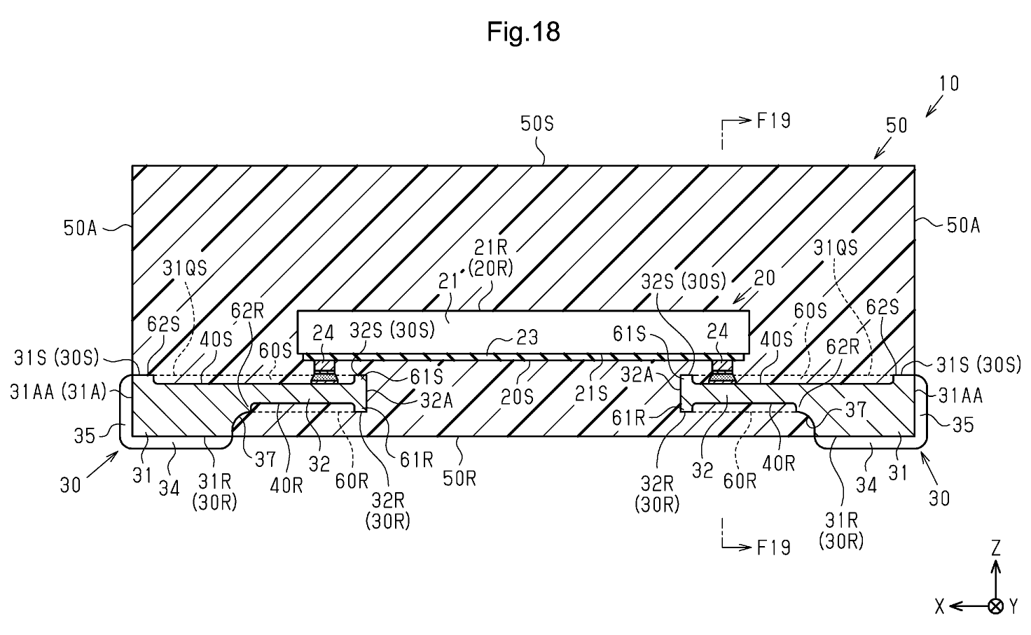

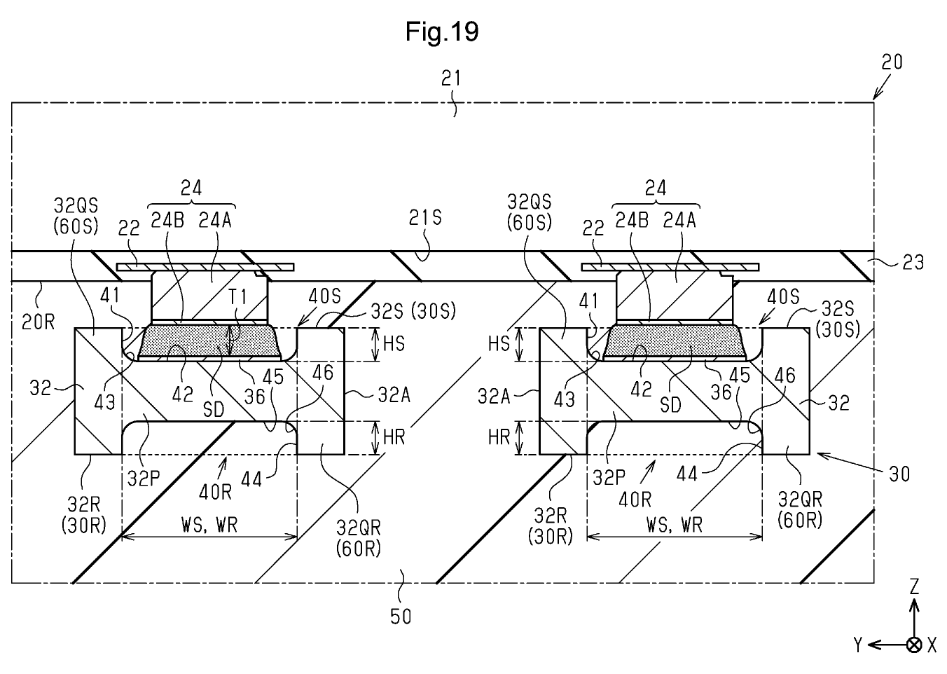

A semiconductor device 10 in accordance with a third embodiment will now be described with reference to FIGS. 18 and 19. The semiconductor device 10 of the second embodiment mainly differs from the semiconductor device 10 of the first embodiment in the structure of the terminals 30, particularly, the number of grooves 40. The description hereafter will focus on the differences from the semiconductor device 10 of the first embodiment. Same reference characters are given to those components that are the same as the corresponding components of the semiconductor device 10 of the first embodiment, and such components will not be described in detail.

### Structure of Semiconductor Device

FIG. 18 is a schematic cross-sectional view showing the structure of the semiconductor device 10 in accordance with the third embodiment. The cross section of FIG. 18 is taken at the same position as that of FIG. 4. FIG. 19 is a schematic cross-sectional view taken along line F19-F19 shown in FIG. 18, showing the structure of part of the semiconductor device 10 in accordance with the third embodiment.

As shown in FIG. 18, the groove 40 formed in each terminal 30 includes a head surface groove 40S and a back surface groove 40R. The head surface groove 40S is recessed from the terminal head surface 30S toward the terminal back surface 30R. For example, the head surface groove 40S has the same structure as the groove 40 of the first embodiment shown in FIGS. 4 to 7. The back surface groove 40R is recessed from the mount portion back surface 32R of the mount portion 32 toward the terminal head surface 30S. For example, the back surface groove 40R has the same structure as the groove 40 of the second embodiment shown in FIGS. 15 to 17.

Each terminal 30 includes a head surface wall portion 60S formed by the head surface groove 40S that is recessed from the terminal head surface 30S toward the terminal back surface 30R. The head surface wall portion 60S is located at two sides of the terminal 30 in the second direction. The head surface wall portion 60S extends in the first direction. Since the head surface groove 40S has the same structure as the groove 40 of the first embodiment, the head surface wall portion 60S is the same as the wall portion 60 of the first embodiment. Accordingly, the terminal portion 31 includes a wall portion 31QS in the same manner as the first embodiment. Further, the mount portion 32 includes a wall portion 32QS in the same manner as the first embodiment. The head surface wall portion 60S is formed by the wall portions 31QS and 32Q. In the third embodiment, the wall portion 31QS is the same as the wall portion 31Q of the first embodiment, and the wall portion 32QS is the same as the wall portion 32Q of the first embodiment.

Furthermore, the mount portion 32 includes a distal end connecting wall 61S in the same manner as the first embodiment. The terminal portion 31 includes a basal end connecting wall 62S in the same manner as the first embodiment. The distal end connecting wall 61S is the same as the distal end connecting wall 61 of the first embodiment, and the basal end connecting wall 62S is the same as the basal end connecting wall 62 of the first embodiment.

Each terminal 30 includes a back surface wall portion 60R formed by the back surface groove 40R that is recessed from the mount portion back surface 32R toward the mount portion head surface 32S. The back surface wall portion 60R is located at two sides of the mount portion 32 in the second direction. The back surface wall portion 60R extends in the first direction. Since the back surface groove 40R is the same as the groove 40 of the second embodiment, the back surface wall portion 60R is the same as the wall portion 60 of the second embodiment. Accordingly, the mount portion 32 includes a wall portion 32QR in the same manner as the first embodiment. The wall portion 32QR is the same as the wall portion 32Q of the second embodiment.

Further, the mount portion 32 includes a distal end connecting wall 61R and a basal end connecting wall 62R in the same manner as the second embodiment. The distal end connecting wall 61R is the same as the distal end connecting wall 61 of the second embodiment, and the basal end connecting wall 62R is the same as the basal end connecting wall 62 of the second embodiment.

As viewed in the first direction, the mount portion 32 is H-shaped due to the head surface groove 40S and the back surface groove 40R formed in the mount portion 32. The mount portion 32 having the head surface groove 40S and the back surface groove 40R includes the base portion 32P, the wall portion 32QS extending upward from the base portion 32P, and the wall portion 32QR extending downward from the base portion 32P.

As shown in FIG. 19, a depth HS of the head surface groove 40S is equal to a depth HR of the back surface groove 40R. Accordingly, the head surface wall portion 60S and the back surface wall portion 60R have the same height. The depth HS of the head surface groove 40S is, for example, equal to the depth H1 of the groove 40 of the first embodiment (refer to FIG. 5). A width WS of the head surface groove 40S is equal to a width WR of the back surface groove 40R. The width WS of the head surface groove 40S is, for example, equal to the width W1 of the groove 40 of the first embodiment (refer to FIG. 5). The width WR of the back surface groove 40R is, for example, equal to the width W3 of the groove 40 of the second embodiment (refer to FIG. 17). Although not shown in the drawings, the length of the head surface groove 40S in the first direction is greater than the length of the back surface groove 40R in the first direction. Accordingly, the length of the head surface wall portion 60S in the first direction is greater than the length of the back surface wall portion 60R in the first direction.

### Method for Manufacturing Semiconductor Device

An example of a method for manufacturing the semiconductor device 10 in accordance with the third embodiment will now be described. The method for manufacturing the semiconductor device 10 in accordance with the third embodiment differs from the method for manufacturing the semiconductor device 10 in accordance with the first embodiment in that the head surface groove 40S and the back surface groove 40R are formed in the mount portion 32. More specifically, in the method for manufacturing the semiconductor device 10 of the third embodiment, the step of preparing the terminals 30 includes a step of forming the head surface groove 40S and the back surface groove 40R in the mount portion 32 by etching the mount portion 32.

In an example, a head surface resist covers a portion of the lead frame 830 that corresponds to the terminal head surface 30S of the terminal 30, except for a region in which the head surface groove 40S is to be formed. In an example, the head surface resist covers two opposite ends, in the second direction, of a region of the lead frame 830 that corresponds to the mount portion head surface 32S. The head surface resist also covers two opposite ends, in the second direction, of a region of the lead frame 830 that corresponds to the terminal portion head surface 31S. Then, the region exposed from the head surface resist is etched. This forms the head surface groove 40S in the central part of the mount portion back surface 32R in the second direction and the central part of the terminal portion head surface 31S in the second direction.

Subsequently, a resist covers a portion of the lead portion 831 that corresponds to the mount portion back surface 32R of the mount portion 32, except for a region in which the back surface groove 40R is to be formed. In an example, the resist covers two opposite ends, in the second direction, of a region of the lead portion 831 that corresponds to the mount portion back surface 32R. Then, the region exposed from the resist is etched. This forms the back surface groove 40R in the central part of the mount portion back surface 32R in the second direction.

As described above, forming the groove 40 includes a step of forming the head surface groove 40S that is recessed from the mount portion head surface 32S, which serves as a region of the lead frame 830 corresponding to the mount portion 32, toward the mount portion back surface 32R. Further, forming the groove 40 includes forming the head surface groove 40S that is recessed from the terminal portion head surface 31S, which serves as a region of the lead frame 830 corresponding to the terminal portion 31, toward the terminal portion back surface 31R. Furthermore, forming the groove 40 includes a step of forming the back surface groove 40R that is recessed from the mount portion back surface 32R, which serves as a region of the lead frame 830 corresponding to the mount portion 32, toward the mount portion head surface 32S.

As a result of such steps, the mount portion 32 includes the base portion 32P, the wall portion 32QS extending upward from the base portion 32P, the wall portion 32QR extending downward from the base portion 32P, the distal end connecting walls 61S and 61R, and the basal end connecting wall 62R. Afterwards, the head surface resist and the back surface resist are removed. The subsequent steps are the same as those of the method for manufacturing the semiconductor device 10 in accordance with the first embodiment. The semiconductor device 10 in accordance with the third embodiment has the same advantages as the first and second embodiments.

### Fourth Embodiment

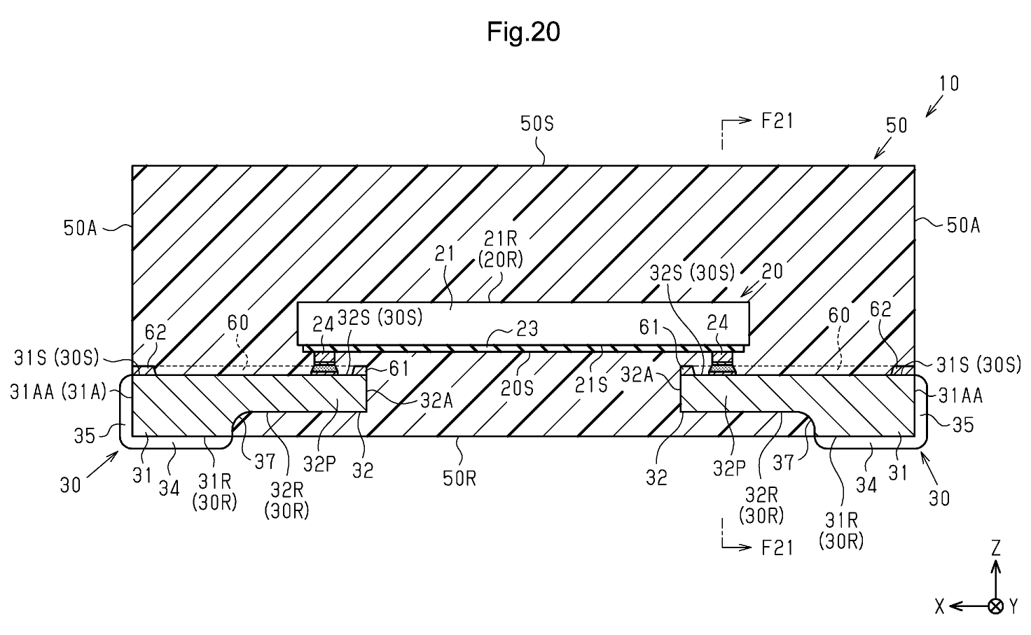

A semiconductor device 10 in accordance with a fourth embodiment will now be described with reference to FIGS. 20 to 22. The semiconductor device 10 of the fourth embodiment mainly differs from the semiconductor device 10 of the first embodiment in the structure of the terminal 30, particularly, the wall portion 60 is disposed instead of forming the groove 40. The description hereafter will focus on the differences from the semiconductor device 10 of the first embodiment. Same reference characters are given to those components that are the same as the corresponding components of the semiconductor device 10 of the first embodiment, and such components will not be described in detail.

### Structure of Semiconductor Device

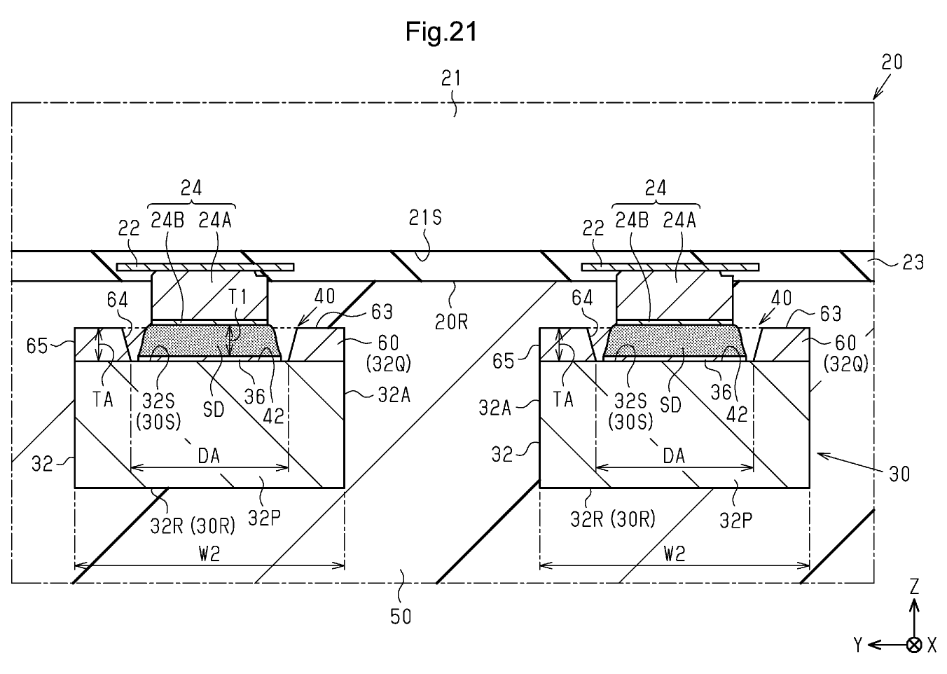

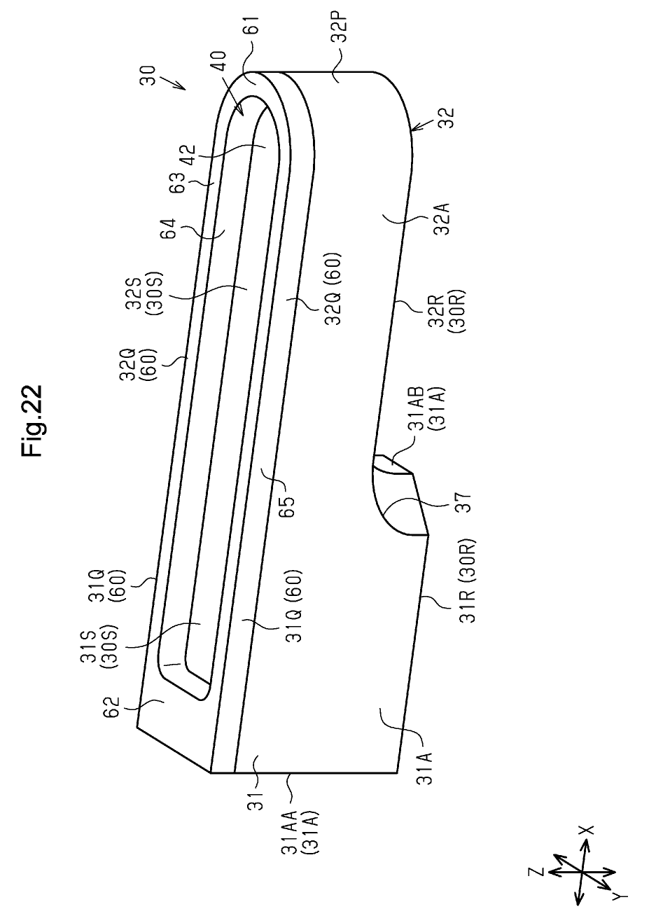

FIG. 20 is a schematic cross-sectional view showing the structure of the semiconductor device 10 in accordance with the fourth embodiment. The cross section of FIG. 20 is taken at the same position as that of FIG. 4. FIG. 21 is a schematic cross-sectional view taken along line F21-F21 shown in FIG. 20, showing the structure of part of the semiconductor device 10 in accordance with the fourth embodiment. FIG. 22 is a schematic perspective view showing the structure of one of the terminals 30. To simplify illustration, FIG. 22 does not show the barrier layer 36.

As shown in FIG. 20, the terminals 30 each include the wall portion 60 extending upward from the terminal head surface 30S in at least the mount portion 32. The wall portion 60 is located at two opposite ends of the terminal 30 in the second direction orthogonal to both the Z-direction and the first direction. The wall portion 60 extends in the first direction. The wall portion 60 is separate from and the terminal 30.

The wall portion 60 is formed by, for example, a metal film. The metal film is formed on the terminal head surface 30S. In an example, the wall portion 60 and the terminal 30 are formed from the same material. In an example, the wall portion 60 is formed from a material containing Cu. The material of the wall portion 60 may be changed. That is, the wall portion 60 and the terminals 30 may be formed from different materials.

As shown in FIG. 22, the wall portion 60 extends over both the terminal portion 31 and the mount portion 32. The mount portion 32 includes the distal end connecting wall 61 at a distal end part of the mount portion 32. The distal end connecting wall 61 connects the wall portion 60 located at two sides of the mount portion 32 in the second direction. The terminal portion 31 includes the basal end connecting wall 62 that connects the wall portion 60 located at two sides of the mount portion 32 in the second direction. In the fourth embodiment, the wall portion 60, the distal end connecting wall 61, the basal end connecting wall 62, and the terminal head surface 30S form the groove 40. The terminal head surface 30S defines the bottom surface 42 of the groove 40.

As shown in FIG. 21, in the fourth embodiment, the mount portion 32 includes the base portion 32P having a flat plate shape, and the wall portion 32Q disposed on the base portion 32P. In the fourth embodiment, the head surface of the base portion 32P defines the mount portion head surface 32S, and the back surface of the base portion 32P defines the mount portion back surface 32R. The wall portion 32Q is separate from the base portion 32P. The wall portion 32Q extends upward from the mount portion head surface 32S. Also, the distal end connecting wall 61 is disposed on the base portion 32P. The distal end connecting wall 61 is integrated with the wall portion 32Q. That is, the distal end connecting wall 61 is separate from the base portion 32P. In the same manner as the first embodiment, in plan view, the distal end connecting wall 61 has a semicircular shape that conforms to the distal end part of the mount portion 32.

Further, the terminal portion 31 includes the wall portion 31Q that is continuous with the wall portion 32Q. The wall portion 31Q defines part of the wall portion 60. In the fourth embodiment, the wall portion 31Q and the wall portion 32Q are integrally formed as an integrated structure. That is, the wall portion 60 is formed by the wall portions 31Q and 32Q. Accordingly, the wall portion 31Q is separate from the base portion 32P. Also, the basal end connecting wall 62 is arranged on the terminal portion head surface 31S of the terminal portion 31. The basal end connecting wall 62 is integrated with the wall portion 31Q. That is, the basal end connecting wall 62 is separate from the base portion 32P.

As shown in FIG. 21, the chip terminal 24 of the semiconductor chip 20 is mounted on the mount portion head surface 32S of the mount portion 32. In an example, the barrier layer 36 is formed on the mount portion head surface 32S. The chip terminal 24 and the barrier layer 36 are bonded by the conductive bonding material SD.

The wall portion 60 includes a wall portion head surface 63, a wall portion inner surface 64, and a wall portion outer surface 65.

The wall portion head surface 63 is, for example, flat and orthogonal to the Z-direction. The wall portion inner surface 64 is an inclined surface inclined toward the center of the terminal 30 in the second direction as the wall portion inner surface 64 extends from the wall portion head surface 63 toward the terminal head surface 30S. The wall portion outer surface 65 is a flat surface extending in the Z-direction and in the first direction. In an example, the wall portion outer surface 65 is flush with the mount portion side surface 32A of the mount portion 32.

The thickness of a portion of the mount portion 32 that does not include the wall portion 60 or the distal end connecting wall 61 is equal to 1/2 of the thickness of the terminal portion 31. Accordingly, the thickness of a portion of the mount portion 32 that includes the wall portion 60 is greater than 1/2 of the thickness of the terminal portion 31. That is, the mount portion 32 includes a portion that is thicker than 1/2 of the thickness of the terminal portion 31.

A height TA of the wall portion 60 is greater than or equal to the thickness T1 of the conductive bonding material SD. The distal end surface of the chip terminal 24, that is, a surface of the barrier layer 24B contacting the conductive bonding material SD, may be located at the same position as the wall portion head surface 63 of the wall portion 60 in the Z-direction, or may be located closer to the mount portion back surface 32R than the wall portion head surface 63 is. That is, when the height TA of the wall portion 60 is equal to a sum of the thickness T1 of the conductive bonding material SD and the thickness of the barrier layer 36, the distal end surface of the chip terminal 24 is located at the same position as the wall portion head surface 63 in the Z-direction. When the height TA of the wall portion 60 is less than the sum of the thickness T1 of the conductive bonding material SD and the thickness of the barrier layer 36, the distal end surface of the chip terminal 24 is located at a side of the wall portion head surface 63 opposite to the mount portion head surface 32S in the Z-direction. Furthermore, the surface of the barrier layer 24B contacting the conductive bonding material SD may be located closer to the mount portion head surface 32S than the wall portion head surface 63 in the Z-direction. That is, when the height TA of the wall portion 60 is greater than the sum of the thickness T1 of the conductive bonding material SD and the thickness of the barrier layer 36, the distal end surface of the chip terminal 24 is located closer to the mount portion head surface 32S than the wall portion head surface 63 is in the Z-direction. In an example, the height TA of the wall portion 60 is 10 μm or less.

A distance DA between two sides of the wall portion 60 in the second direction is greater than the diameter of the chip terminal 24 of the semiconductor chip 20. The distance DA may be defined by, for example, the distance between opposing parts of the wall portion inner surface 64 in the second direction. The distance DA is greater than 1/2 of the width W2 of the mount portion 32. In an example, the distance DA is approximately 2/3 of the width W2 of the mount portion 32.

### Method for Manufacturing Semiconductor Device

An example of a method for manufacturing the semiconductor device 10 in accordance with the fourth embodiment will now be described. the method for manufacturing the semiconductor device 10 in accordance with the fourth embodiment differs from the method for manufacturing the semiconductor device 10 in accordance with the first embodiment in that the wall portion 60 is disposed on the mount portion 32. more specifically, in the method for manufacturing the semiconductor device 10 of the fourth embodiment, the step of preparing the terminals 30 includes a step of forming the wall portion 60 on the mount portion 32. in an example, a resist covers a portion of the terminal head surface 30s, except for a region in which the wall portion 60 is to be formed. more specifically, the resist is located between two opposite ends of the lead portion 831 of the lead frame 830 in the second direction. the resist extends in the first direction. in other words, the two opposite ends of the lead portion 831 in the second direction are exposed from the resist. this exposed region extends in the first direction. subsequently, a metal film is sputtered, for example, on the portion of the terminal head surface 30s exposed from the resist to form the wall portion 60. this forms the wall portion 60 separate from the base portion 32p (mount portion 32). as a result, the wall portion 60 is disposed at the two opposite ends of the terminal head surface 30s of the lead portion 831 in the second direction, such that the wall portion 60 extends upward from the terminal head surface 30s. the wall portion 60 extends in the first direction. the resist is then removed. the subsequent steps are the same as those of the method for manufacturing the semiconductor device 10 in accordance with the first embodiment.

### Advantages of the Fourth Embodiment

The semiconductor device 10 of the fourth embodiment has the following advantages in addition to advantages (1-6) and (1-7) of the first embodiment.

(4-1) The semiconductor device 10 includes the terminals 30, the semiconductor chip 20, and the encapsulation resin 50. The semiconductor chip 20 is mounted on the terminals 30. The encapsulation resin 50 encapsulates the terminals 30 and the semiconductor chip 20. The terminals 30 each include the terminal head surface 30S, and the terminal back surface 30R facing away from the terminal head surface 30S. The terminals 30 each include the terminal portion 31, the mount portion 32, and the wall portion 60. The terminal portion 31 includes the terminal portion back surface 31R exposed from the encapsulation resin 50. The terminal portion back surface 31R is part of the terminal back surface 30R. The mount portion 32 extends from the terminal portion 31 in the first direction orthogonal to the Z-direction, which is the thickness-wise direction of the terminals 30. The semiconductor chip 20 is mounted on the mount portion 32. The wall portion 60 extends upward from the terminal head surface 30S in at least mount portion 32. The wall portion 60 is located at two opposite ends of the terminal 30 in a second direction orthogonal to both the Z-direction and the first direction. The wall portion 60 extends in the first direction.

With this structure, the wall portion 60 is formed on the mount portion 32, so that the mount portion 32 resists bending as compared to a mount portion without the wall portion 60. Therefore, in the step of cleaning the terminals 30 and the semiconductor chip 20, the mount portion 32 will not be vibrated in the Z-direction by the sprayed pure water and the chemical agent. This avoids a situation in which vibration of the mount portion 32 applies force to the conductive bonding material SD, thereby stabilizing the electrical connection between the mount portion 32 and the semiconductor chip 20.

(4-2) The wall portion 60 extends from the terminal portion 31 to the distal end part of the mount portion 32.

With this structure, the wall portion 60 is formed in a relatively large region of the mount portion 32 in the first direction, so that the mount portion 32 resists bending. Therefore, in the step of cleaning the terminals 30 and the semiconductor chip 20, the mount portion 32 will not be vibrated in the Z-direction by the sprayed pure water and the chemical agent.

(4-3) The wall portion 60 extends over both the terminal portion 31 and the mount portion 32.

With this structure, the mount portion 32 resists bending at an end part of the mount portion 32 located relatively close to the terminal portion 31. Therefore, in the step of cleaning the terminals 30 and the semiconductor chip 20, the mount portion 32 will not be vibrated in the Z-direction by the sprayed pure water and the chemical agent.

(4-4) The method for manufacturing the semiconductor device 10 includes preparing the terminals 30, mounting the semiconductor chip 20 on the terminals 30, and forming the encapsulation resin 50 to encapsulate the terminals 30 and the semiconductor chip 20. The terminals 30 each include the terminal head surface 30S, and the terminal back surface 30R facing away from the terminal head surface 30S. The preparing the terminals 30 includes forming the terminal portion 31, the mount portion 32, and the wall portion 60. The mount portion 32 extends from the terminal portion 31 in the first direction orthogonal to the Z-direction, which is the thickness-wise direction of the terminals 30. The mount portion 32 includes the base portion 32P configured to receive the semiconductor chip 20. The base portion 32P has a flat plate shape. The wall portion 60 is separate from the base portion 32P. The wall portion 60 extends upward from the terminal head surface 30S in at least the mount portion 32. The wall portion 60 extends in the first direction. The wall portion 60 is located at two opposite ends of the mount portion 32 in the second direction orthogonal to both the Z-direction and the first direction.

With this structure, the wall portion 60 is formed on the mount portion 32, so that the mount portion 32 resists bending as compared to a mount portion without the wall portion 60. This avoids a situation in which an external force applied to the mount portion 32 is transferred to the conductive bonding material SD, thereby stabilizing the electrical connection between the mount portion 32 and the semiconductor chip 20.

### Fifth Embodiment

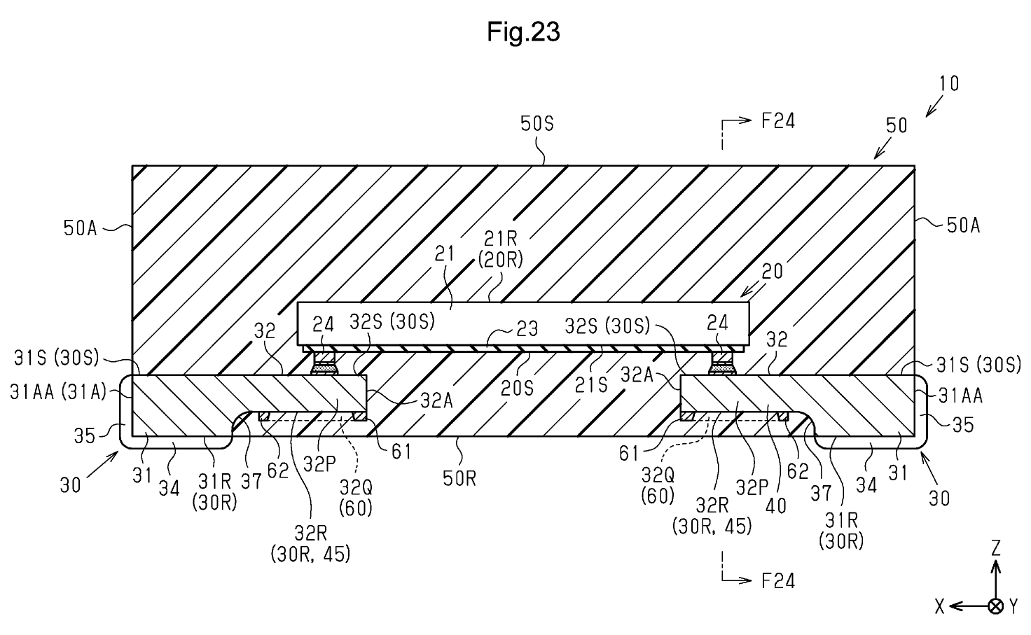

A semiconductor device 10 in accordance with a fifth embodiment will now be described with reference to FIGS. 23 to 25. The semiconductor device 10 of the fifth embodiment mainly differs from the semiconductor device 10 of the fourth embodiment in the structure of the terminal 30, particularly, the location of the wall portion 60. The description hereafter will focus on the differences from the semiconductor device 10 of the fourth embodiment. Same reference characters are given to those components that are the same as the corresponding components of the semiconductor device 10 of the fourth embodiment, and such components will not be described in detail.

### Structure of Semiconductor Device

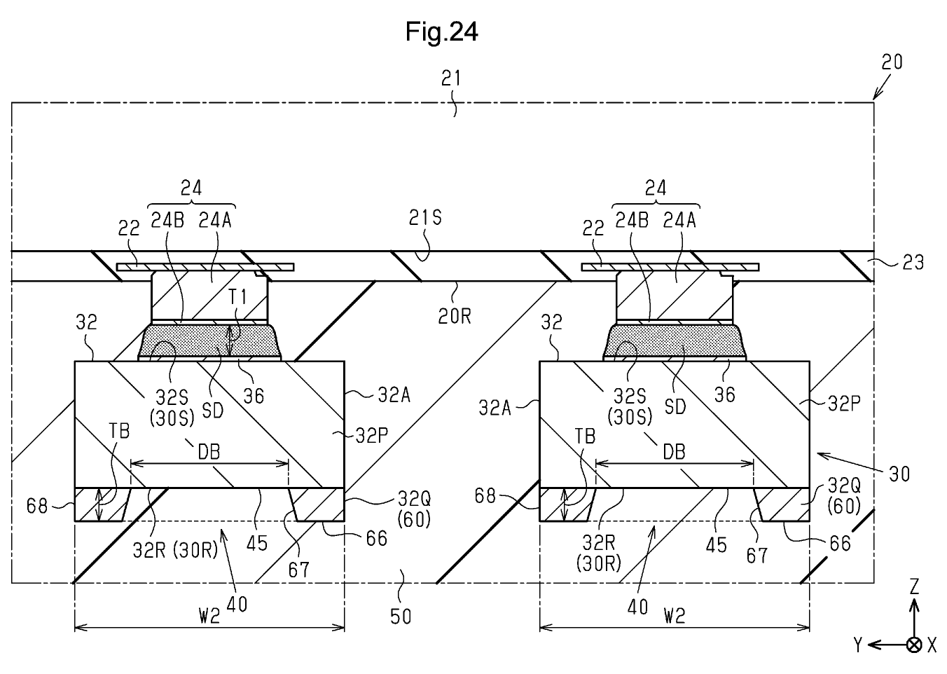

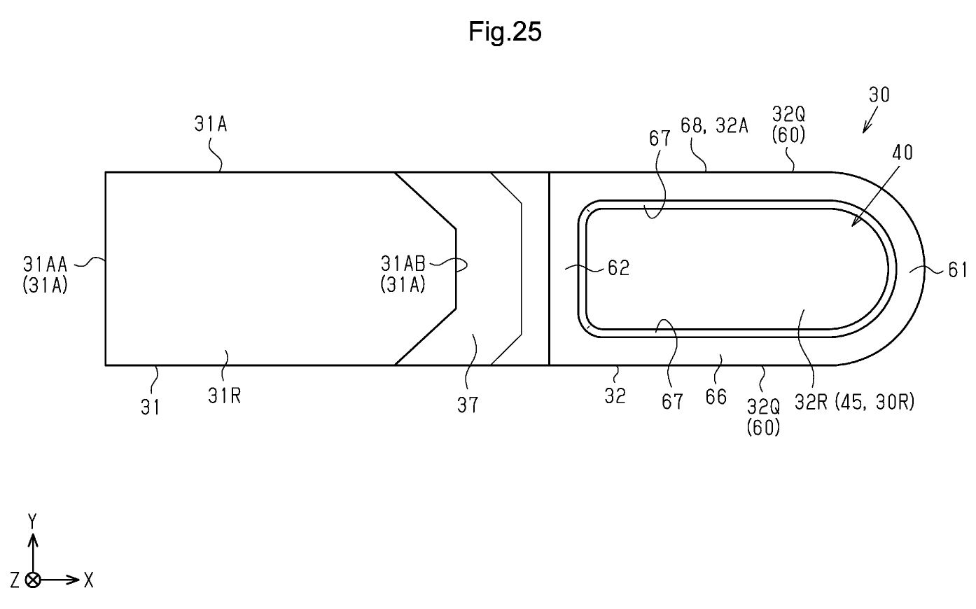

FIG. 23 is a schematic cross-sectional view showing the structure of the semiconductor device 10 in accordance with the fifth embodiment. The cross section of FIG. 23 is taken at the same position as that of FIG. 4. FIG. 24 is a schematic cross-sectional view taken along line F24-F24 shown in FIG. 23, showing the structure of part of the semiconductor device 10 in accordance with the fifth embodiment. FIG. 25 is a schematic back view showing the structure of one of the terminals 30.

As shown in FIGS. 24 and 25, in the fifth embodiment, the wall portion 60 is disposed on the mount portion back surface 32R of the mount portion 32. The wall portion 60 projects from the mount portion back surface 32R away from the terminal head surface 30S (mount portion head surface 32S). The wall portion 60 is located at two opposite ends of the terminal 30 in the second direction orthogonal to both the Z-direction and the first direction. The wall portion 60 extends in the first direction. Although not shown in the drawings, each terminal 30 includes the wall portion 60. The wall portion 60 of the fifth embodiment is an example of “back surface wall portion”.

The wall portion 60 is formed by, for example, a metal film. The metal film is formed on the mount portion back surface 32R. In an example, the wall portion 60 and the terminal 30 are formed from the same material. In an example, the wall portion 60 is formed from a material containing Cu. The material of the wall portion 60 may be changed. That is, the wall portion 60 and the terminals 30 may be formed from different materials.

The wall portion 60 is formed on the mount portion 32. The wall portion 60 is not formed on the terminal portion 31. As shown in FIG. 25, the mount portion 32 includes the distal end connecting wall 61 located at the distal end part of the mount portion 32, and the basal end connecting wall 62 located at the basal end part of the mount portion 32. The distal end connecting wall 61 connects the wall portion 60 located at two sides of the mount portion 32 in the second direction. The basal end connecting wall 62 connects the wall portion 60 located at two sides of the mount portion 32 in the second direction. In the fifth embodiment, the wall portion 60, the distal end connecting wall 61, the basal end connecting wall 62, and the mount portion back surface 32R form the groove 40. The mount portion back surface 32R defines the bottom surface 45 of the groove 40.

In the fifth embodiment, the mount portion 32 includes the base portion 32P and the wall portion 32Q. The base portion 32P has a flat plate shape (refer to FIG. 24). The wall portion 32Q projects from the back surface of the base portion 32P. The head surface of the base portion 32P defines the mount portion head surface 32S, and the back surface of the base portion 32P defines the mount portion back surface 32R. In other words, the wall portion 32Q extends downward from the mount portion back surface 32R. The wall portion 32Q is separate from the base portion 32P. Further, the distal end connecting wall 61 projects from the back surface of the base portion 32P. In other words, the distal end connecting wall 61 extends downward from the mount portion back surface 32R. The distal end connecting wall 61 is integrated with the wall portion 32Q. That is, the distal end connecting wall 61 is separate from the base portion 32P. In the same manner as the fourth embodiment, in plan view, the distal end connecting wall 61 has a semicircular shape that conforms to the distal end part of the mount portion 32. The basal end connecting wall 62 projects from the mount portion back surface 32R at the basal end part of the mount portion 32. The basal end connecting wall 62 extends downward from the mount portion back surface 32R. The basal end connecting wall 62 is integrated with the wall portion 32Q. That is, the basal end connecting wall 62 is separate from the base portion 32P.

As shown in FIG. 23, the thickness of a portion of the mount portion 32 that does not include the wall portion 60 or the distal end connecting wall 61 is equal to 1/2 of the thickness of the terminal portion 31. Accordingly, the thickness of a portion of the mount portion 32 that includes the wall portion 60 is greater than 1/2 of the thickness of the terminal portion 31. That is, the mount portion 32 includes a portion that is thicker than 1/2 of the thickness of the terminal portion 31.

In the fifth embodiment, the wall portion 60 is not formed on the mount portion head surface 32S of the mount portion 32. In other words, in the fifth embodiment, the mount portion head surface 32S is flat and orthogonal to the Z-direction.

As shown in FIG. 24, the wall portion 60 of the fifth embodiment includes a wall portion back surface 66, a wall portion inner surface 67, and a wall portion outer surface 68.

The wall portion back surface 66 is, for example, flat and orthogonal to the Z-direction. The wall portion inner surface 67 is an inclined surface inclined toward the center of the terminal 30 in the second direction as the wall portion inner surface 67 extends from the wall portion back surface 66 toward the terminal back surface 30R. The wall portion outer surface 68 is a flat surface extending in the Z-direction and in the first direction. In an example, the wall portion outer surface 68 is flush with the mount portion side surface 32A of the mount portion 32.

The thickness of a portion of the mount portion 32 that does not include the wall portion 60 or the distal end connecting wall 61 is equal to 1/2 of the thickness of the terminal portion 31. Accordingly, the thickness of a portion of the mount portion 32 that includes the wall portion 60 is greater than 1/2 of the thickness of the terminal portion 31. That is, the mount portion 32 includes a portion that is thicker than 1/2 of the thickness of the terminal portion 31. A height TB of the wall portion 60 of the fifth embodiment is, for example, equal to the height TA of the wall portion 60 of the fourth embodiment (refer to FIG. 21). A distance DB between opposing parts of the wall portion 60 of the fifth embodiment in the second direction is, for example, equal to the distance DA between opposing parts of the wall portion 60 of the fourth embodiment in the second direction (refer to FIG. 21).

### Method for Manufacturing Semiconductor Device

An example of a method for manufacturing the semiconductor device 10 in accordance with the fifth embodiment will now be described. The method for manufacturing the semiconductor device 10 in accordance with the fifth embodiment differs from the method for manufacturing the semiconductor device 10 in accordance with the fourth embodiment in the position of the mount portion 32 where the wall portion 60 is disposed. More specifically, in the method for manufacturing the semiconductor device 10 of the fifth embodiment, the step of preparing the terminals 30 includes a step of forming the wall portion 60 on the mount portion back surface 32R of the mount portion 32. In an example, a resist covers a portion of the mount portion back surface 32R, except for a region in which the wall portion 60 is to be formed. More specifically, the resist is located between two opposite ends, in the second direction, of the mount portion back surface 32R included in a region of the lead portion 831 of the lead frame 830 that corresponds to the mount portion 32. The resist extends in the first direction. In other words, the two opposite ends of the mount portion back surface 32R in the second direction are exposed from the resist. This exposed region extends in the first direction. Subsequently, a metal film is sputtered, for example, on the portion of the mount portion back surface 32R exposed from the resist to form the wall portion 60. This forms the wall portion 60 separate from the base portion 32P (mount portion 32). As a result, the wall portion 60 is disposed at the two opposite ends of the mount portion back surface 32R of the lead portion 831 in the second direction, such that the wall portion 60 extends downward from the mount portion back surface 32R. The wall portion 60 extends in the first direction. The resist is then removed. The subsequent steps are the same as those of the method for manufacturing the semiconductor device 10 in accordance with the first embodiment.

### Advantages of the Fifth Embodiment

The semiconductor device 10 of the fifth embodiment has the following advantages in addition to advantage (4-2) of the fourth embodiment.

(5-1) The semiconductor device 10 includes the terminals 30, the semiconductor chip 20, and the encapsulation resin 50. The semiconductor chip 20 is mounted on the terminals 30. The encapsulation resin 50 encapsulates the terminals 30 and the semiconductor chip 20. The terminals 30 each include the terminal head surface 30S, and the terminal back surface 30R facing away from the terminal head surface 30S. The terminals 30 each include the terminal portion 31, the mount portion 32, and the wall portion 60. The terminal portion 31 includes the terminal portion back surface 31R exposed from the encapsulation resin 50. The terminal portion back surface 31R is part of the terminal back surface 30R. The mount portion 32 extends from the terminal portion 31 in the first direction orthogonal to the Z-direction, which is the thickness-wise direction of the terminals 30. The semiconductor chip 20 is mounted on the mount portion 32. The mount portion 32 includes the mount portion back surface 32R disposed in the encapsulation resin 50. The mount portion back surface 32R defines part of the terminal back surface 30R. The semiconductor device 10 includes wall portion 60 extending in the first direction. The wall portion 60 is located at opposite two ends of the mount portion back surface 32R in the second direction orthogonal to both the Z-direction and the first direction.

With this structure, the wall portion 60 is disposed on the mount portion back surface 32R of the mount portion 32, so that the mount portion 32 resists bending as compared to a mount portion that does not include the wall portion 60. Therefore, in the step of cleaning the terminals 30 and the semiconductor chip 20, the mount portion 32 will not be vibrated in the Z-direction by the sprayed pure water and the chemical agent. This avoids a situation in which vibration of the mount portion 32 applies force to the conductive bonding material SD, thereby stabilizing the electrical connection between the mount portion 32 and the semiconductor chip 20.

(5-2) The method for manufacturing the semiconductor device 10 includes preparing the terminals 30, mounting the semiconductor chip 20 on the terminals 30, and forming the encapsulation resin 50 to encapsulate the terminals 30 and the semiconductor chip 20. The terminals 30 each include the terminal head surface 30S, and the terminal back surface 30R facing away from the terminal head surface 30S. The preparing the terminals 30 includes forming the terminal portion 31, the mount portion 32, and the wall portion 60. The mount portion 32 extends from the terminal portion 31 in the first direction orthogonal to the Z-direction, which is the thickness-wise direction of the terminals 30. The mount portion 32 includes the base portion 32P configured to receive the semiconductor chip 20. The base portion 32P has a flat plate shape. The wall portion 60 is separate from the base portion 32P. The mount portion 32 includes the mount portion back surface 32R disposed in the encapsulation resin 50. The mount portion back surface 32R defines part of the terminal back surface 30R. The wall portion 60 extends downward from the mount portion back surface 32R. The wall portion 60 is located at two opposite ends of the mount portion back surface 32R in the second direction. The wall portion 60 extends in the first direction.

With this structure, the wall portion 60 is disposed on the mount portion back surface 32R of the mount portion 32, so that the mount portion 32 resists bending as compared to a mount portion that does not include the wall portion 60. This avoids a situation in which an external force applied to the mount portion 32 is transferred to the conductive bonding material SD, thereby stabilizing the electrical connection between the mount portion 32 and the semiconductor chip 20.

### Sixth Embodiment

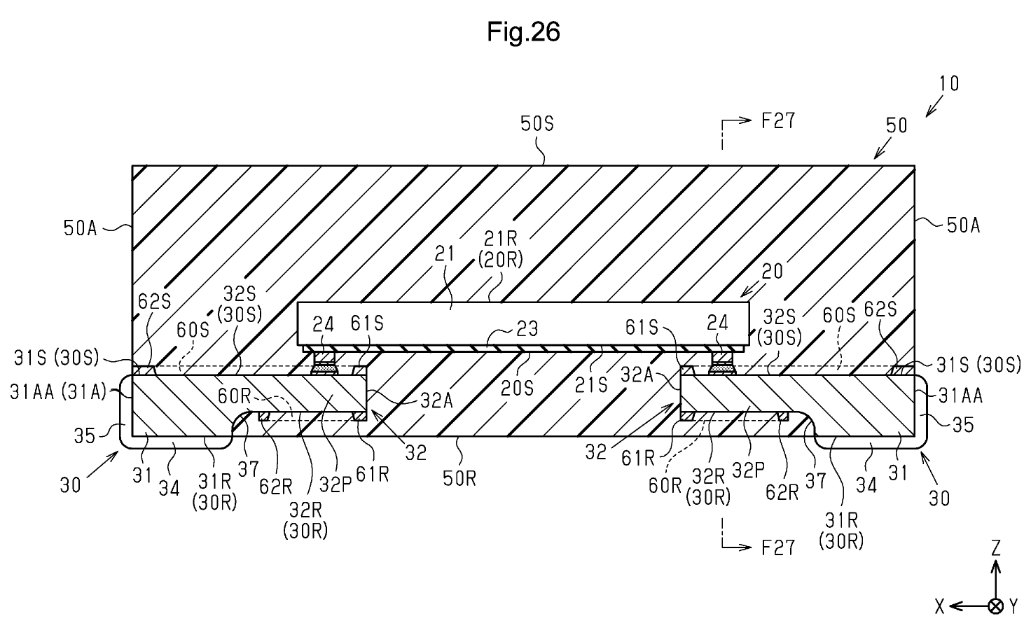

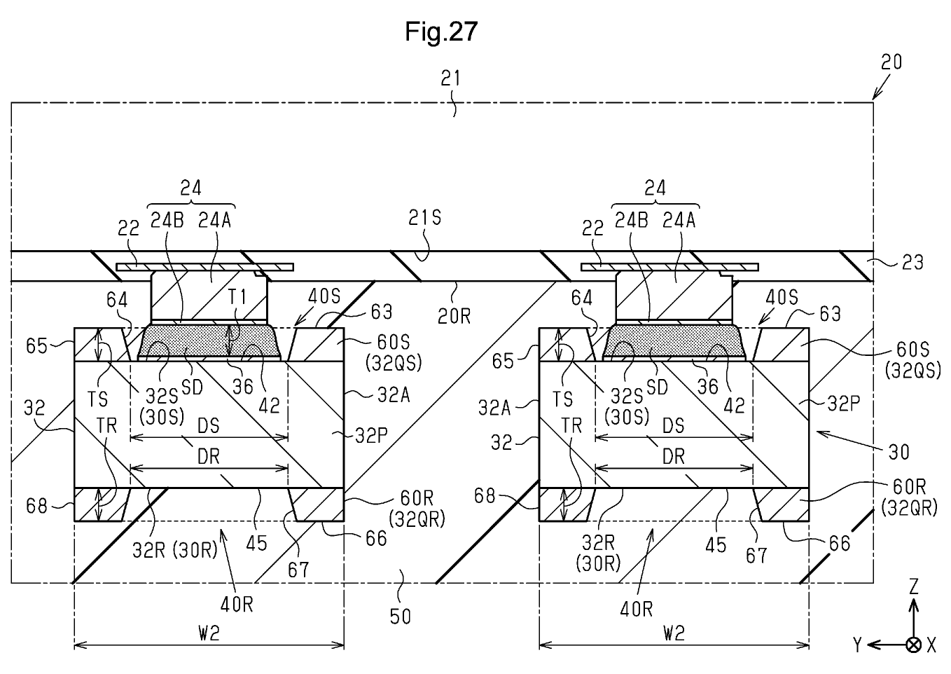

A semiconductor device 10 in accordance with a sixth embodiment will now be described with reference to FIGS. 26 and 27. The semiconductor device 10 of the fifth embodiment mainly differs from the semiconductor device 10 of the fourth embodiment in the structure of the terminals 30, particularly, the positions and number of wall portions 60. The description hereafter will focus on the differences from the semiconductor device 10 of the fourth embodiment. Same reference characters are given to those components that are the same as the corresponding components of the semiconductor device 10 of the fourth embodiment, and such components will not be described in detail.

### Structure of Semiconductor Device

FIG. 26 is a schematic cross-sectional view showing the structure of the semiconductor device 10 in accordance with the sixth embodiment. The cross section of FIG. 26 is taken at the same position as that of FIG. 4. FIG. 27 is a schematic cross-sectional view taken along line F27-F27 shown in FIG. 26, showing the structure of part of the semiconductor device 10 in accordance with the sixth embodiment.

As shown in FIG. 26, the wall portion 60 formed on each terminal 30 includes the head surface wall portion 60S and the back surface wall portion 60R. The head surface wall portion 60S extends upward from the terminal head surface 30S in the Z-direction. The structure of the head surface wall portion 60S is the same as, for example, that of the wall portion 60 of the fourth embodiment shown in FIGS. 20 to 22. The back surface wall portion 60R projects from the mount portion back surface 32R of the mount portion 32 toward a side opposite to the terminal head surface 30S. The structure of the back surface wall portion 60R is the same as, for example, that of the wall portion 60 of the fifth embodiment shown in FIGS. 23 to 25.

The head surface wall portion 60S is located at two sides of the terminal 30 in the second direction. The head surface wall portion 60S extends in the first direction. The head surface wall portion 60S is defined by the wall portions 31QS (not shown) and 32QS. The wall portion 31QS is the same as the wall portion 31Q of the fourth embodiment. Further, the mount portion 32 includes the distal end connecting wall 61S in the same manner as the fourth embodiment. The terminal portion 31 includes the basal end connecting wall 62S in the same manner as the fourth embodiment. The distal end connecting wall 61S is the same as the distal end connecting wall 61 of the fourth embodiment, and the basal end connecting wall 62S is the same as the basal end connecting wall 62 of the fourth embodiment. The head surface wall portion 60S, the distal end connecting wall 61S, the basal end connecting wall 62S, and the terminal head surface 30S form the head surface groove 40S. The terminal head surface 30S defines the bottom surface 42 of the head surface groove 40S.

Each terminal 30 includes the back surface wall portion 60R formed by the back surface groove 40R that is recessed from the mount portion back surface 32R toward the mount portion head surface 32S. The back surface wall portion 60R is located at two sides of the mount portion 32 in the second direction. The back surface wall portion 60R extends in the first direction. Since the back surface groove 40R is the same as the groove 40 of the second embodiment, the back surface wall portion 60R is the same as the wall portion 60 of the second embodiment. Further, the mount portion 32 includes the distal end connecting wall 61R and the basal end connecting wall 62R in the same manner as the second embodiment. The distal end connecting wall 61R is the same as the distal end connecting wall 61 of the second embodiment, and the basal end connecting wall 62R is the same as the basal end connecting wall 62 of the second embodiment.

As viewed in the first direction, the mount portion 32 is H-shaped due to the head surface wall portion 60S and the back surface wall portion 60R formed on the mount portion 32. The mount portion 32 having the head surface wall portion 60S and the back surface wall portion 60R includes the base portion 32P, the head surface wall portion 60S (wall portion 32Q) extending upward from the base portion 32P, and the back surface wall portion 60R extending downward from the base portion 32P.

As shown in FIG. 27, a height TS of the head surface wall portion 60S is equal to a height TR of the back surface wall portion 60R. The height TS of the head surface wall portion 60S is equal to, for example, the height TA of the wall portion 60 of the fourth embodiment (refer to FIG. 21). A distance DS between opposing parts of the head surface wall portion 60S in the second direction is equal to a distance DR between opposing parts of the back surface wall portion 60R in the second direction. The distance DS between opposing parts of the head surface wall portion 60S in the second direction is equal to, for example, the distance DA between opposing parts of the wall portion 60 of the fourth embodiment in the second direction (refer to FIG. 21). The distance DR between opposing parts of the back surface wall portion 60R in the second direction is equal to, for example, the distance DB between opposing parts of the wall portion 60 of the fifth embodiment in the second direction (refer to FIG. 24). Although not shown in the drawings, the head surface wall portion 60S is longer than the back surface wall portion 60R.

### Method for Manufacturing Semiconductor Device

An example of a method for manufacturing the semiconductor device 10 in accordance with the sixth embodiment will now be described. The method for manufacturing the semiconductor device 10 in accordance with the sixth embodiment differs from the method for manufacturing the semiconductor device 10 in accordance with the fourth embodiment in that the head surface wall portion 60S and the back surface wall portion 60R are formed on the mount portion 32. More specifically, in the method for manufacturing the semiconductor device 10 of the sixth embodiment, the step of preparing the terminals 30 includes a step of forming the head surface groove 40S in the mount portion head surface 32S, and a step of forming the back surface groove 40R in the mount portion back surface 32R. In an example, a head surface resist covers a portion of the terminal head surface 30S of the terminal 30, except for a region in which the head surface wall portion 60S is to be formed. Then, a back surface resist covers a portion of the mount portion back surface 32R of the mount portion 32, except for a region in which the back surface wall portion 60R is to be formed. Subsequently, sputtering is performed on the portion of the terminal head surface 30S exposed from the head surface resist and the portion of the mount portion back surface 32R exposed from the back surface resist. This forms the head surface wall portion 60S on the terminal head surface 30S, and the back surface wall portion 60R on the mount portion back surface 32R. Afterwards, the head surface resist and the back surface resist are removed. The subsequent steps are the same as those of the method for manufacturing the semiconductor device 10 in accordance with the fourth embodiment. The semiconductor device 10 in accordance with the sixth embodiment has the same advantages as the first and fifth embodiments.

### Seventh Embodiment

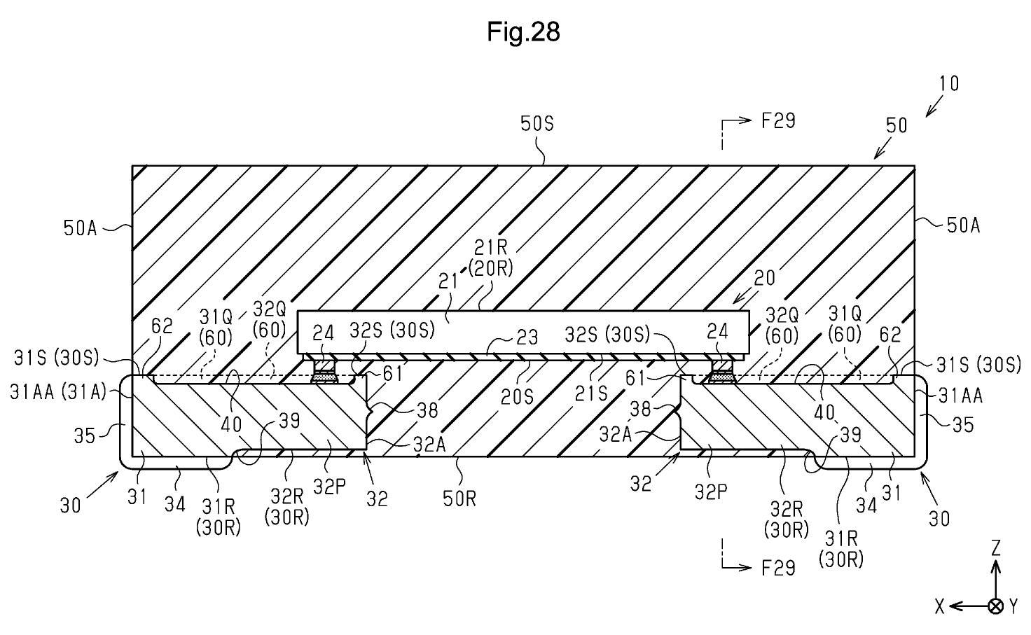

A semiconductor device 10 in accordance with a seventh embodiment will now be described with reference to FIGS. 28 to 34. The semiconductor device 10 of the seventh embodiment mainly differs from the semiconductor device 10 of the first embodiment in the structure of the terminals 30, particularly, the thickness of the mount portion 32. The description hereafter will focus on the differences from the semiconductor device 10 of the first embodiment. Same reference characters are given to those components that are the same as the corresponding components of the semiconductor device 10 of the first embodiment, and such components will not be described in detail.

### Structure of Semiconductor Device

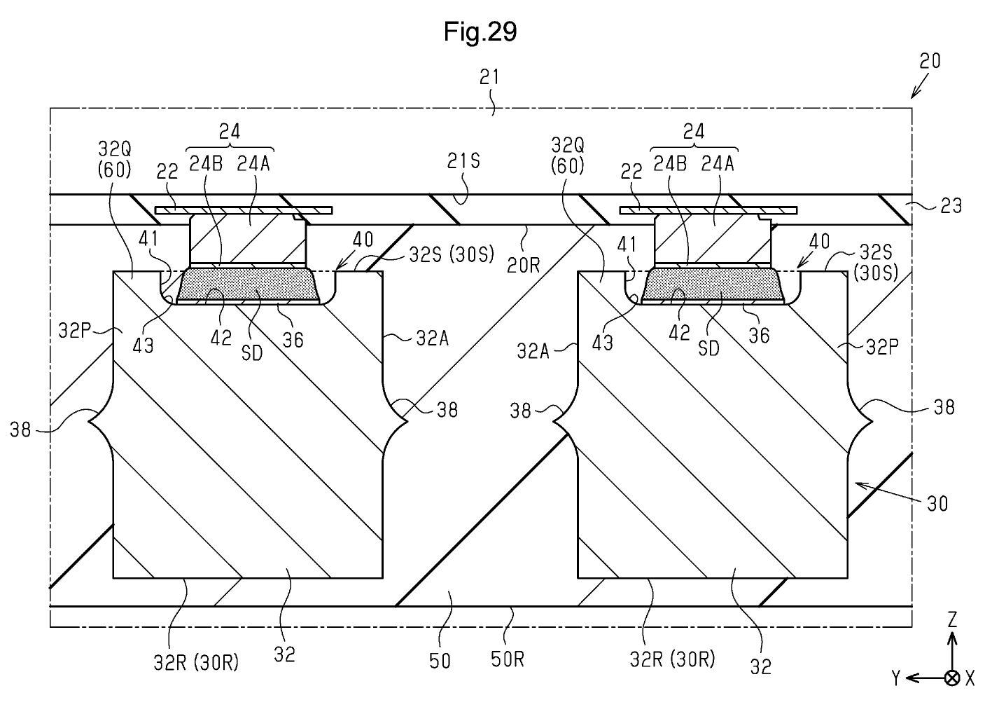

The structure of the terminals 30 in accordance with the seventh embodiment will now be described with reference to FIGS. 28 and 29. FIG. 28 is a schematic cross-sectional view showing the structure of the semiconductor device 10 in accordance with the seventh embodiment. The cross section of FIG. 28 is taken at the same position as that of FIG. 4. FIG. 29 is a schematic cross-sectional view taken along line F29-F29 shown in FIG. 28, showing the structure of part of the semiconductor device 10 in accordance with the seventh embodiment.

As shown in FIG. 28, the terminal 30 of the seventh embodiment differs from the terminal 30 of the first embodiment in a ratio of the thickness of the mount portion 32 to the thickness of the terminal portion 31. Specifically, in the first embodiment, the ratio of the thickness of the mount portion 32 to the thickness of the terminal portion 31 is less than or equal to 1/2. More specifically, in a portion of the mount portion 32 that does not include the groove 40, the ratio of the thickness of the mount portion 32 to the thickness of the terminal portion 31 is 1/2. Further, in a portion of the mount portion 32 that includes the groove 40, the ratio of the thickness of the mount portion 32 to the thickness of the terminal portion 31 is less than 1/2. In contrast, in the terminal 30 of the seventh embodiment, a ratio of the thickness of a portion of the mount portion 32 that does not include the groove 40 to the thickness of the terminal portion 31 is greater than 1/2. In an example, the ratio of the thickness of the portion of the mount portion 32 that does not include the groove 40 to the thickness of the terminal portion 31 is greater than 2/3. In an example, the ratio of the thickness of the portion of the mount portion 32 that does not include the groove 40 to the thickness of the terminal portion 31 is less than or equal to 4/5.

As shown in FIG. 29, the portion of the mount portion 32 that does not include the groove 40 has the same thickness as, for example, the mount portion 32. The portion of the mount portion 32 that includes the groove 40 is thinner than, for example, the mount portion 32.

As shown in FIG. 28, the mount portion side surface 32A of the mount portion 32 includes a projection 38. For example, the projection 38 extends along the entire mount portion side surface 32A. The projection 38 also extends along the terminal portion side surface 31A of the terminal portion 31. However, the projection 38 is not included in the exposed side surface 31AA of the terminal portion side surface 31A of the terminal portion 31.

The projection 38 is disposed on an intermediate part of the mount portion 32 in the Z-direction. That is, the projection 38 is located at a position separated from both the terminal head surface 30S and the terminal back surface 30R in the Z-direction. In other words, the projection 38 is disposed on an intermediate part of the mount portion side surface 32A of the mount portion 32 in the Z-direction. The mount portion side surface 32A includes a distal end surface, which is an end surface of the mount portion 32 in the first direction. Accordingly, the projection 38 is located at an intermediate part of the distal end surface of the mount portion 32 in the Z-direction. In other words, the projection 38 extends along the entire distal end surface of the mount portion 32 in the second direction. The phrase “an intermediate part of the mount portion 32 in the Z-direction” refers to a region between a head side end part of the mount portion 32 in the Z-direction, including the mount portion head surface 32S, and a back side end part of the mount portion 32 in the Z-direction, including the mount portion back surface 32R.

In an example, the projection 38 is disposed at a central part of the mount portion side surface 32A of the mount portion 32 in the Z-direction. In other words, the projection 38 is located at a central part of the distal end surface of the mount portion 32 in the Z-direction. When a difference between the distance from the mount portion head surface 32S to the projection 38 and the distance from the mount portion back surface 32R to the projection 38 is, for example, within 10% of the distance from the mount portion head surface 32S to the projection 38, the projection 38 may be considered to be located at a central part of the mount portion side surface 32A of the mount portion 32 in the Z-direction.

The projection 38 includes two side surfaces facing away from each other in the Z-direction. The two side surfaces are curved toward each other as the two side surfaces extend toward the distal end of the projection 38. Accordingly, the projection 38 has a tapered shape.

The terminals 30 each include a step 39. The step 39 is formed so that the mount portion back surface 32R, which is a portion of the terminal back surface 30R corresponding to the mount portion 32, is located closer to the terminal head surface 30S than the terminal portion back surface 31R of the terminal portion 31 is. The step 39 includes a curved surface. In the seventh embodiment, the step 39 is formed by a curved surface.

The dimension of the step 39 in the Z-direction is less than the thickness of the mount portion 32. The dimension of the step 39 in the thickness-wise direction may be defined by the distance from the terminal portion back surface 31R to the mount portion back surface 32R in the Z-direction. The dimension of the step 39 in the thickness-wise direction is equal to the thickness of a portion of the encapsulation resin 50 covering the mount portion back surface 32R. The thickness of the portion of the encapsulation resin 50 covering the mount portion back surface 32R is less than 1/2 of the thickness of the mount portion 32. Further, the dimension of the step 39 in the Z-direction is less than the distance from the mount portion back surface 32R to the projection 38 in the Z-direction. Also, the dimension of the step 39 in the Z-direction is less than the distance from the mount portion head surface 32S to the projection 38.

As shown in FIGS. 28 and 29, each terminal 30 includes the groove 40. The shape and location of the groove 40 are the same as, for example, those of the groove 40 of the first embodiment. In an example, the projection 38 is located closer to the terminal back surface 30R than the bottom surface 42 of the groove 40 is. The chip terminals 24 of the semiconductor chip 20 are mounted on the terminals 30 in the same manner as the first embodiment.

Each terminal 30 includes the wall portion 60 formed by the groove 40, which is recessed from the terminal head surface 30S toward the terminal back surface 30R. The wall portion 60 is located at two sides of the terminal 30 in the second direction. The wall portion 60 extends in the first direction.

As viewed in the first direction, the mount portion 32 is U-shaped due to the groove 40 formed in the mount portion 32. Since the groove 40 is recessed from the mount portion head surface 32S toward the mount portion back surface 32R, the mount portion 32 includes a base portion 32P and a wall portion 32Q. The wall portion 32Q extends upward from the base portion 32P. In the seventh embodiment, the base portion 32P and the wall portion 32Q are integrally formed as an integrated structure. The wall portion 32Q extends in the first direction at two opposite ends of the mount portion 32 in the second direction. The wall portion 32Q defines part of the wall portion 60. The base portion 32P includes the mount portion back surface 32R. The wall portion 32Q includes the mount portion head surface 32S. In the seventh embodiment, the thickness of the base portion 32P is greater than 1/2 of the thickness of the terminal portion 31. The thickness of the base portion 32P may be defined by the distance from the bottom surface 42 of the groove 40 to the mount portion back surface 32R in the Z-direction.

As shown in FIG. 28, since the groove 40 is recessed from the terminal portion head surface 31S toward the terminal portion back surface 31R, the terminal portion 31 includes the wall portion 31Q continuous with the wall portion 32Q of the mount portion 32. The wall portion 31Q is the same as the wall portion 31Q of the first embodiment. The wall portion 31Q defines part of the wall portion 60. In the seventh embodiment, the wall portion 31Q and the wall portion 32Q are integrally formed as an integrated structure. That is, the wall portion 60 is formed by the wall portions 31Q and 32Q.

### Method for Manufacturing Semiconductor Device

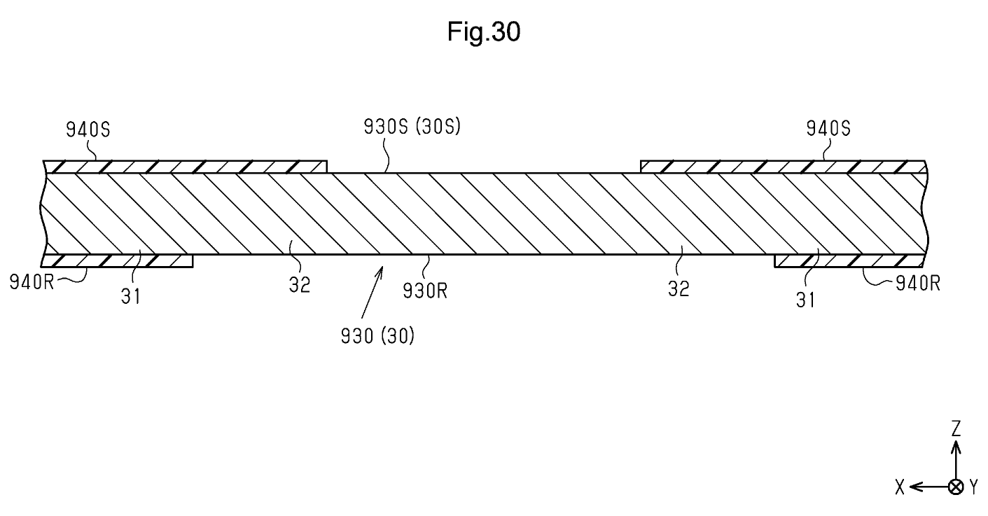

An example of a method for manufacturing the semiconductor device 10 in accordance with the seventh embodiment, particularly, a method for manufacturing the terminals 30, will now be described with reference to FIGS. 30 to 34. FIGS. 30 to 34 are schematic cross-sectional views of a metal plate 930 illustrating an example of the step of preparing the terminals 30.

As shown in FIG. 30, in the step of preparing the terminals 30, the metal plate 930 is first prepared. The metal plate 930 has a flat plate shape and has a thickness-wise direction parallel to the Z-direction. The metal plate 930 includes a head surface 930S and a back surface 930R, facing away from each other in the Z-direction.

Then, a head surface resist 940S is formed on the head surface 930S of the metal plate 930, and a back surface resist 940R is formed on the back surface 930R of the metal plate 930. The head surface resist 940S and the back surface resist 940R may each be, for example, a photoresist. The head surface resist 940S covers a portion of the terminal 30 that corresponds to the terminal head surface 30S. The back surface resist 940R covers a portion of the terminal 30 that corresponds to the terminal portion back surface 31R of the terminal portion 31.

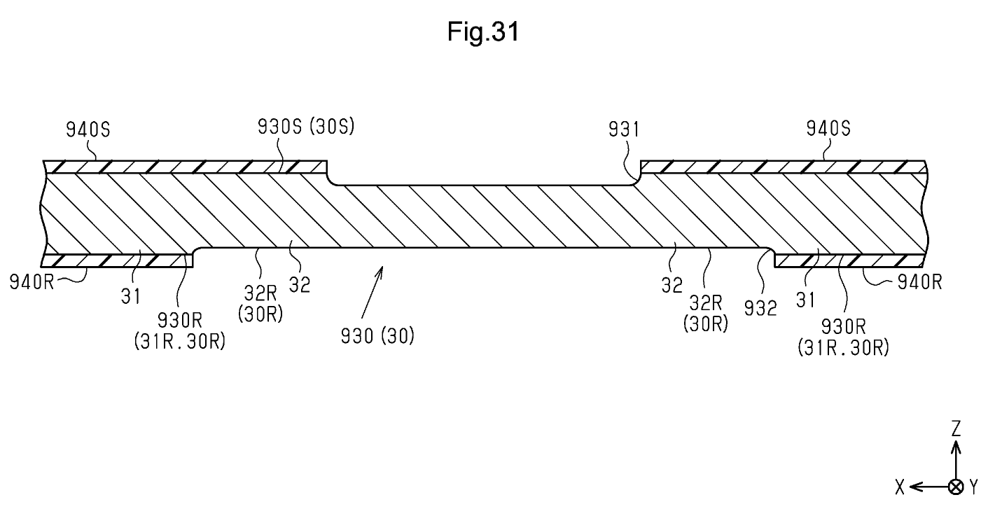

As shown in FIG. 31, the step of preparing the terminals 30 includes a step of etching the head surface 930S and the back surface 930R of the metal plate 930. In this step, a portion of the head surface 930S of the metal plate 930 exposed from the head surface resist 940S is partially etched in the Z-direction. This forms a recess 931 recessed from the head surface 930S of the metal plate 930. The recess 931 is formed in a portion of the head surface 930S of the metal plate 930 that does not correspond to the terminal 30. A portion of the back surface 930R of the metal plate 930 exposed from the back surface resist 940R is partially etched in the Z-direction. This forms a recess 932 recessed from the back surface 930R of the metal plate 930. The recess 932 includes the mount portion 32. The recess 932 defines the mount portion back surface 32R of the mount portion 32. In this manner, the step of preparing the terminals 30 includes a step of forming the recess 931 by etching part of the head surface 930S of the metal plate 930. The step of preparing the terminals 30 also includes a step of forming the recess 932 by etching part of the back surface 930R of the metal plate 930.

The recess 932 includes the step 39 and part of the terminal portion 31. The step 39 is formed between the mount portion 32 and the terminal portion 31, so that the step 39 is located closer to the head surface 930S than the terminal portion back surface 31R of the terminal portion 31 is. Accordingly, the step of forming the recess 932 includes a step of forming the terminal portion 31 and the step 39. The depth of the recess 932 is approximately 1/5 of the thickness of the metal plate 930.

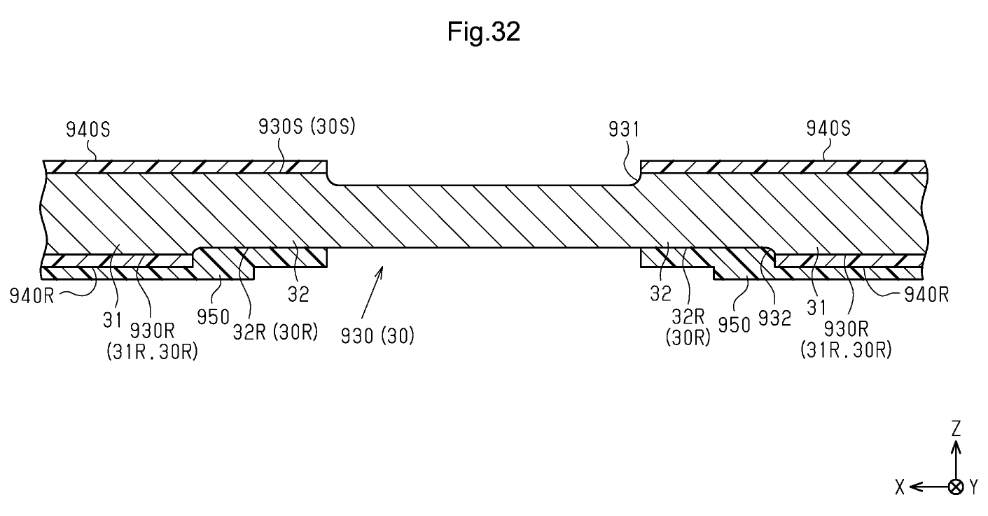

As shown in FIG. 32, in the step of preparing the terminals 30, a back surface resist 950 is formed on the back surface 930R of the metal plate 930. The back surface resist 950 covers the back surface resist 940R and a portion of the back surface 930R of the metal plate 930 that corresponds to the mount portion 32. In the same manner as the head surface resist 940S, the back surface resist 950 exposes a portion of the back surface 930R of the metal plate 930 that does not correspond to the terminal 30.

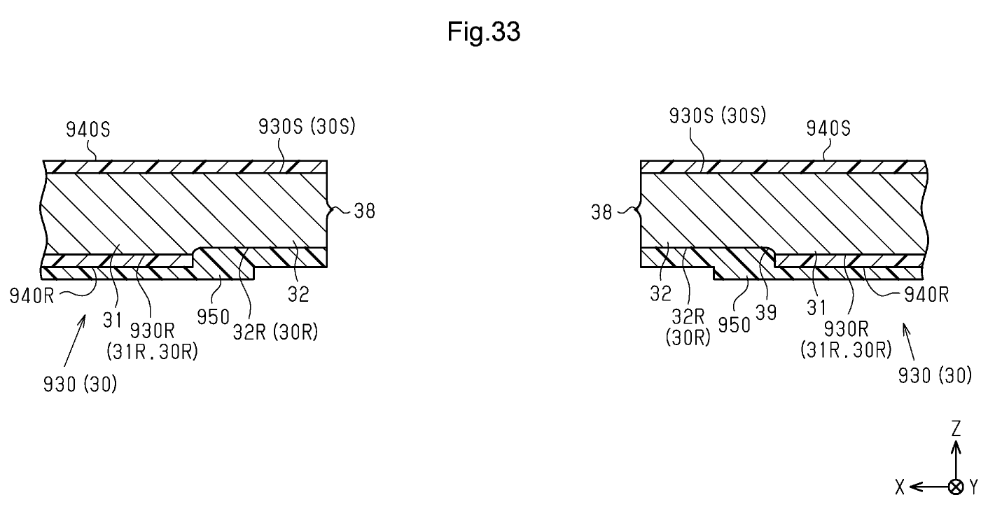

As shown in FIG. 33, the step of preparing the terminals 30 includes a step of forming the mount portion 32 by etching. In this step, the metal plate 930 is etched from both the head surface 930S and the back surface 930R of the metal plate 930. This forms the mount portion 32 and the projection 38. In the step of preparing the terminals 30, the metal plate 930 is selectively removed so as to form the distal end surface in the first direction, and the projection 38 located at an intermediate part of the distal end surface in the Z-direction. The selective removal of the metal plate 930 includes a step of further etching the recess 931 from the head surface 930S of the metal plate 930. In the seventh embodiment, the etching amount of the head surface 930S of the metal plate 930 in the Z-direction is equal to the etching amount of the back surface 930R of the metal plate 930 in the Z-direction. As a result, the projection 38 is located at a central part of the distal end surface of the mount portion 32 in the Z-direction. The projection 38 extends along the entire mount portion side surface 32A of the mount portion 32. After the mount portion 32 is formed, the head surface resist 940S, the back surface resist 940R, and the back surface resist 950 are removed.

The depth of the recess 932 is approximately 1/5 of the thickness of the metal plate 930, and the thickness of the terminal portion 31 is equal to the thickness of the metal plate 930. Accordingly, a ratio of the thickness of the mount portion 32 to the thickness of the terminal portion 31 is greater than 1/2. Further, the ratio of the thickness of the mount portion 32 to the thickness of the terminal portion 31 is less than or equal to 4/5. As described above, the step of preparing the terminals 30 includes a step of forming the terminal portion 31 and the mount portion 32, so that the ratio of the thickness of the mount portion 32 to the thickness of the terminal portion 31 is greater than 1/2. The step of preparing the terminals 30 includes a step of forming the terminal portion 31 and the mount portion 32, so that the ratio of the thickness of the mount portion 32 to the thickness of the terminal portion 31 is less than or equal to 4/5.

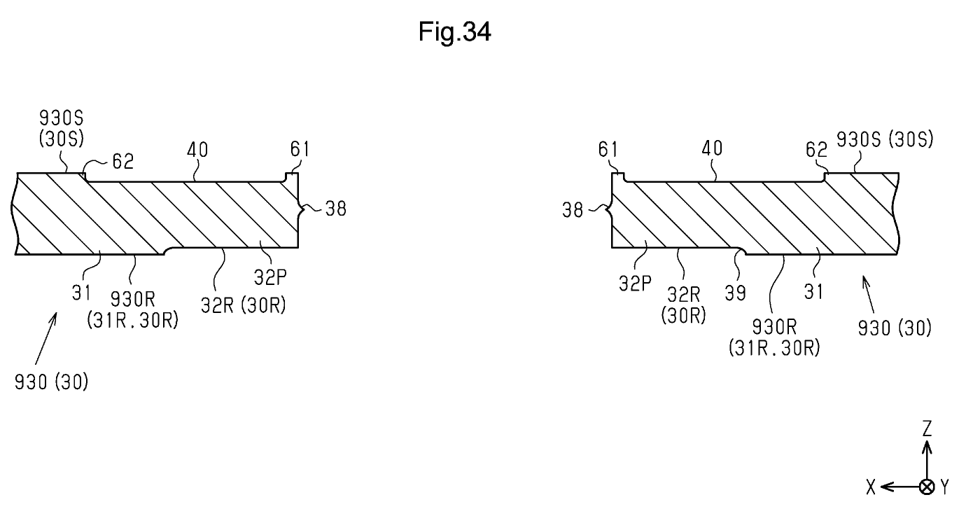

As shown in FIG. 34, the step of preparing the terminals 30 includes a step of forming groove 40. The groove 40 is formed in a portion of the metal plate 930 that corresponds to the mount portion 32. In other words, the step of preparing the terminals 30 includes a step of forming the groove 40 in the mount portion 32 by etching at least the mount portion 32. The groove 40 is located between two opposite ends of the mount portion 32 in the second direction orthogonal to both the first direction and the Z-direction. The groove 40 extends in the first direction. In the seventh embodiment, the groove 40 is formed in a portion of the lead portion 831 that corresponds to both the terminal portion 31 and the mount portion 32.

The groove 40 is formed by partially etching at least the mount portion 32 from the head surface 930S of the metal plate 930. That is, the step of preparing the terminals 30 includes a step of forming the groove 40 by partially etching at least the mount portion 32 from the head surface 930S of the metal plate 930. In the seventh embodiment, the groove 40 is formed by partially etching both the terminal portion 31 and the mount portion 32 from the head surface 930S of the metal plate 930. When the groove 40 is formed, the mount portion 32 includes the base portion 32P, the wall portion 32Q (wall portion 60 in FIG. 29) extending upward from the base portion 32P, and the distal end connecting wall 61. Further, a portion of the lead portion 831 that corresponds to the terminal portion 31 includes the basal end connecting wall 62. The wall portion 32Q is located at two opposite ends of the mount portion 32 in the second direction, such that the mount portion 32 is U-shaped as viewed in the first direction. The subsequent steps are the same as those of the method for manufacturing the semiconductor device 10 in accordance with the first embodiment.

### Advantages of the Seventh Embodiment

The semiconductor device 10 in accordance with the seventh embodiment has the following advantages.

(7-1) The semiconductor device 10 of the seventh embodiment has advantages (1-1) to (1-9) of the first embodiment.

(7-2) The thickness of the mount portion 32 of the terminal 30 is greater than 1/2 of the thickness of the terminal portion 31.

With this structure, the mount portion 32 will not be deformed by an external force as compared to a structure in which the thickness of the mount portion 32 is less than 1/2 of the thickness of the terminal portion 31. For example, in the step of cleaning the terminals 30 and the semiconductor chip 20, the mount portion 32 will not be vibrated by pressure applied to the terminal 30 in the Z-direction. This stabilizes the electrical connection between the mount portion 32 and the semiconductor chip 20. In addition, when the thickness of the mount portion 32 is relatively large, the electrical resistance of the terminal 30 is relatively small. This allows for supply of a large current to the terminals 30.

(7-3) The terminals 30 each include the projection 38 located at an intermediate part of the mount portion side surface 32A of the mount portion 32 in the Z-direction.

With this structure, the projection 38, and the head surface end part and the back surface end part of the mount portion 32 disperse stress of the encapsulation resin 50. Therefore, as compared to when the projection 38 is disposed on the head surface end part or the back surface end part of the mount portion 32, stress will not concentrate in the head surface end part or the back surface end part of the mount portion 32.

(7-4) The projection 38 extends along the entirety of the mount portion side surface 32A of the mount portion 32.

With this structure, as compared to a structure in which the projection 38 extends along only part of the mount portion side surface 32A, stress will not concentrate in part of the mount portion side surface 32A. Also, the terminal 30 is less likely to separate from the encapsulation resin 50.

(7-5) The projection 38 includes the two side surfaces facing away from each other in the Z-direction. The two side surfaces are formed by curved surfaces.

With this structure, the projection 38 has a smoother shape as compared to when the projection 38 is, for example, rectangular. This avoids concentration of stress in the projection 38.

(7-6) The terminals 30 each include the step 39. The step 39 is formed so that the mount portion back surface 32R, which is a portion of the terminal back surface 30R corresponding to the mount portion 32, is located closer to the terminal head surface 30S than the terminal portion back surface 31R of the terminal portion 31 is. The dimension of the step 39 in the Z-direction is less than the thickness of the mount portion 32.

With this structure, the thickness of the mount portion 32 is relatively large as compared to a structure in which the dimension of the step 39 in the Z-direction is greater than the thickness of the mount portion 32. This allows the mount portion 32 to resist bending caused by an external force.

(7-7) The step 39 includes a curved surface.

With this structure, concentration of stress in the step 39 is reduced as compared to a structure in which the step 39 is a flat surface. This restricts deformation of the mount portion 32 caused by concentration of stress in the step 39.

(7-8) The dimension of the step 39 in the Z-direction is less than the distance from the mount portion back surface 32R to the projection 38 of the mount portion 32 in the Z-direction.

With this structure, the thickness of the mount portion 32 is relatively large as compared to a structure in which the dimension of the step 39 in the Z-direction is greater than the distance from between the mount portion back surface 32R to the projection 38 in the Z-direction. This allows the mount portion 32 to resist bending caused by an external force.

### Modified Examples

The above-described embodiments may be modified as follows. The modified examples described below may be combined as long as there is no technical contradiction.

### Combinations of the Embodiments

The first to seventh embodiments may be combined as long as the combined modifications remain technically consistent with each other. In an example, the terminal 30 of the seventh embodiment may be combined with the structure of the groove 40 of the second or third embodiment. In another example, the groove 40 may be omitted from the terminal 30 of the seventh embodiment, and then the terminal 30 of the seventh embodiment may be combined with the wall portion 60 of any of the fourth to sixth embodiments. In another example, the terminal 30 of the second embodiment may be combined with the wall portion 60 of the fourth embodiment. In another example, the terminal 30 of the fourth embodiment may be combined with the groove 40 of the second embodiment.

In an example, the terminal 30 of the first or seventh embodiment may be combined with the wall portion 60 of the fourth embodiment. In another example, the terminal 30 of the first or seventh embodiments may be combined with the wall portion 60 of the fifth embodiment. In another example, the terminal 30 of the second embodiment may be combined with the wall portion 60 of the fifth embodiment. In another example, the terminal 30 of the second embodiment may be combined with the wall portion 60 of the fourth embodiment. In another example, the terminal 30 of the third embodiment may be combined with the wall portion 60 (head surface wall portion 60S and back surface wall portion 60R) of any of the fourth to sixth embodiments.

### Modified Examples of Groove

In the first embodiment, the groove 40 may be formed in the mount portion 32, and does not have to be formed in the terminal portion 31. Specifically, the groove 40 may extend in the first direction at a position located closer to the distal end part of the mount portion 32 than the terminal portion 31 is. The same modification may be applied to the head surface groove 40S of the third embodiment.

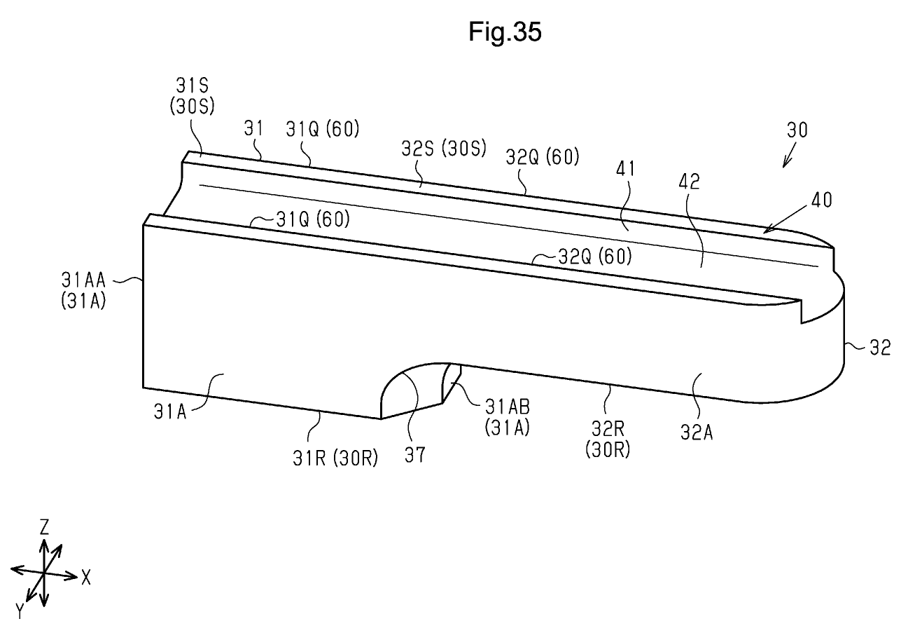

In the first embodiment, the groove 40 may be open in the first direction. In an example, as shown in FIG. 35, the groove 40 may open in the distal end part of the mount portion 32 in the first direction, and open in the terminal portion 31 in the first direction. The same modification may be applied to the head surface groove 40S of the third embodiment. The groove 40 may be open in the distal end part of the mount portion 32 in the first direction, and does not have to open in the terminal portion 31 in the first direction. The groove 40 may be open in the terminal portion 31 in the first direction at a side opposite to the mount portion 32, and does not have to open in the distal end part of the mount portion 32 in the first direction.

In the first embodiment, the groove 40 may be located closer to the terminal portion 31 in the first direction than a region of the mount portion 32 in which the chip terminal 24 of the semiconductor chip 20 is mounted is. In this case, the chip terminal 24 is mounted on the mount portion head surface 32S of the mount portion 32. More specifically, the barrier layer 36 is formed on the region of the mount portion head surface 32S in which the chip terminal 24 is mounted. The chip terminal 24 and the barrier layer 36 are bonded by the conductive bonding material SD. The same modification may be applied to the head surface groove 40S of the third embodiment.

In the second embodiment, the groove 40 may open in the distal end part of the mount portion 32 in the first direction. The same modification may be applied to the back surface groove 40R of the third embodiment.

In the first and second embodiments, the widths W1 and W3 of the groove 40 may be changed.

In the first and second embodiments, the depths H1 and H2 of the groove 40 may be changed.

In the first and second embodiments, the length of the groove 40 in the first direction may be changed.

In the third embodiment, the width WS of the head surface groove 40S may differ from the width WR of the back surface groove 40R. In an example, the width WS of the head surface groove 40S may be greater than the width WR of the back surface groove 40R. In another example, the width WR of the back surface groove 40R may be greater than the width WS of the head surface groove 40S.

In the third embodiment, the depth HS of the head surface groove 40S may differ from the depth HR of the back surface groove 40R. In an example, the depth HS of the head surface groove 40S may be greater than the depth HR of the back surface groove 40R. In another example, the depth HR of the back surface groove 40R may be greater than the depth HS of the head surface groove 40S.

In the third embodiment, the length of the head surface groove 40S in the first direction may be equal to the length of the back surface groove 40R in the first direction. Alternatively, the length of the head surface groove 40S in the first direction may be less than the length of the back surface groove 40R in the first direction.

In the third embodiment, the width WS of the head surface groove 40S may be changed.

In the third embodiment, the depth HS of the head surface groove 40S may be changed.

In the third embodiment, the length of the head surface groove 40S in the first direction may be changed.

In the third embodiment, the width WR of the back surface groove 40R may be changed.

In the third embodiment, the depth HR of the back surface groove 40R may be changed.

In the third embodiment, the length of the back surface groove 40R in the first direction may be changed.

In the seventh embodiment, the width W1 of the groove 40 may be changed.

In the seventh embodiment, the length of the groove 40 in the first direction may be changed.

In the seventh embodiment, the depth H1 of the groove 40 may be greater than the depth H1 of the groove 40 of the first embodiment. In the seventh embodiment, the depth H1 of the groove 40 may be increased within a range in which the mount portion head surface 32S does not contact the chip back surface 20R of the semiconductor chip 20 when the semiconductor chip 20 is mounted on the mount portion 32.

In the first, second, and seventh embodiments, the groove 40 may have any cross-sectional shape taken along a plane that extends in the second direction and the Z-direction.

### Modified Examples of Wall Portion

In the fourth embodiment, the wall portion 60 may be disposed on the mount portion 32, and does not have to be disposed on the terminal portion 31. Specifically, the wall portion 60 may extend in the first direction at a position located closer to the distal end part of the mount portion 32 than the terminal portion 31 is. The same modification may be applied to the head surface wall portion 60S of the sixth embodiment.

In the fourth embodiment, the wall portion 60 may be located closer to the terminal portion 31 in the first direction than a region of the mount portion 32 in which the chip terminal 24 of the semiconductor chip 20 is mounted is. The same modification may be applied to the head surface wall portion 60S of the sixth embodiment.

In the fourth and fifth embodiments, the height TA (TB) of the wall portion 60 may be changed.

In the fourth and fifth embodiments, the distance DA (DB) between opposing parts of the wall portion 60 in the second direction may be changed.

In the fourth and fifth embodiments, the length of the wall portion 60 in the first direction may be changed.

In the sixth embodiment, the height TS of the head surface wall portion 60S may differ from the height TR of the back surface wall portion 60R. In an example, the height TS of the head surface wall portion 60S may be greater than the height TR of the back surface wall portion 60R. In another example, the height TR of the back surface wall portion 60R may be greater than the height TS of the head surface wall portion 60S.

In the sixth embodiment, the distance DS between opposing parts of the head surface wall portion 60S in the second direction may differ from the distance DR between opposing parts of the back surface wall portion 60R in the second direction. In an example, the distance DS between opposing parts of the head surface wall portion 60S in the second direction may be greater than the distance DR between opposing parts of the back surface wall portion 60R in the second direction. In another example, the distance DR between opposing parts of the back surface wall portion 60R in the second direction may be greater than the distance DS between opposing parts of the head surface wall portion 60S in the second direction.

In the sixth embodiment, the length of head surface wall portion 60S in the first direction may be equal to the length of the back surface wall portion 60R in the first direction. Alternatively, the length of the head surface wall portion 60S in the first direction may be less than the length of the back surface wall portion 60R in the first direction.

In the fourth and fifth embodiments, the distal end connecting wall 61 may be omitted from the wall portion 60. In the sixth embodiment, the distal end connecting wall 61 may be omitted from the head surface wall portion 60S. In the sixth embodiment, the distal end connecting wall 61 may be omitted from the back surface wall portion 60R.

In the fourth and fifth embodiments, the basal end connecting wall 62 may be omitted from the wall portion 60. In the sixth embodiment, the basal end connecting wall 62 may be omitted from the head surface wall portion 60S. In the sixth embodiment, the basal end connecting wall 62 may be omitted from the back surface wall portion 60R.

In the fourth to sixth embodiments, the wall portion 60 (head surface wall portion 60S and back surface wall portion 60R) may have any cross-sectional shape taken along a plane that extends in the Z-direction and the second direction. In an example, the wall portion 60 may have a trapezoidal cross section. That is, the wall portion outer surface 65 of the wall portion 60 may be inclined with respect to the Z-direction.

In the fourth and fifth embodiments, the wall portion 60 may be formed from an insulative material, such as a resist, instead of a metal film. In the sixth embodiment, the head surface wall portion 60S may be formed from an insulative material, such as a resist, instead of a metal film. In the sixth embodiment, the back surface wall portion 60R may be formed from an insulative material, such as a resist, instead of a metal film.

### Modified Examples of Semiconductor Device

In the seventh embodiment, the ratio of the thickness of a portion of the mount portion 32 that does not include the groove 40 to the thickness of the terminal portion 31 may be changed. In an example, the ratio of the thickness of the portion of the mount portion 32 that does not include the groove 40 to the thickness of the terminal portion 31 may be greater than 4/5. In another example, the ratio of the thickness of the portion of the mount portion 32 that does not include the groove 40 to the thickness of the terminal portion 31 may be greater than 5/6. In another example, the ratio of the thickness of the portion of the mount portion 32 that does not include the groove 40 to the thickness of the terminal portion 31 may be greater than 9/10.

In each embodiment, the number of terminals 30 may be changed.

In each embodiment, the planar shape of the mount portion 32 of the terminal 30 may be changed.

In each embodiment, the exposed side surface 31AA may be omitted from the terminal portion 31 of at least one of the terminals. That is, the terminal portion 31 of the terminal 30 does not have to be exposed from the encapsulation side surface 50A of the encapsulation resin 50.

### Modified Examples of Method for Manufacturing Semiconductor Device

In the first to third and seventh embodiments, the groove 40 may be formed before forming the base portion 32P of the mount portion 32. In the fourth to sixth embodiments, the wall portion 60 may be formed before forming the base portion 32P of the mount portion 32.

In the third embodiment, the head surface groove 40S and the back surface groove 40R may be formed in the same step. The back surface groove 40R may be formed after forming the head surface groove 40S. The head surface groove 40S may be formed after forming the back surface groove 40R.

In the fourth to sixth embodiments, the wall portion 60, the distal end connecting wall 61, and the basal end connecting wall 62 may be formed separately.

In the sixth embodiment, the head surface wall portion 60S and the back surface wall portion 60R may be formed in the same step. The back surface wall portion 60R may be formed after forming the head surface wall portion 60S. The head surface wall portion 60S may be formed after forming the back surface wall portion 60R.

Various examples described in this specification may be combined as long as there is no technical contradiction.

In the present disclosure, the term “on” includes the meaning of “above” in addition to the meaning of “on” unless otherwise described in the context. Accordingly, for example, a phrase such as “first element disposed on second element” may mean that the first element is directly located on the second element in one embodiment and that the first element is located above the second element without contacting the second element in another embodiment. Therefore, the term “on” does not exclude a structure in which another element is formed between the first element and the second element.

The Z-direction as referred to in this disclosure does not have to be the vertical direction, and does not have to exactly coincide with the vertical direction. Accordingly, in the various structures of the present disclosure, “up” and “down” in the Z-direction as referred to in this specification are not limited to “up” and “down” in the vertical direction. For example, the X-direction may be the vertical direction. Alternatively, the Y-direction may be the vertical direction.

### Clauses

Technical concepts that can be understood from the present disclosure will now be described. Reference characters used in the described embodiment are added to corresponding elements in the clauses to aid understanding without any intention to impose limitations on these elements. The reference characters are given as examples to aid understanding, and are not intended to limit elements to the elements denoted by the reference characters.

Clause A1

A semiconductor device (10), including:

terminals (30), each including a terminal head surface (30S) and a terminal back surface (30R) facing away from the terminal head surface (30S);

a semiconductor chip (20) mounted on the terminals (30); and

an encapsulation resin (50) encapsulating the terminals (30) and the semiconductor chip (20), in which

the terminals (30) each include

a terminal portion (31) including a terminal portion back surface (31R) exposed from the encapsulation resin (50), the terminal portion back surface (31R) being part of the terminal back surface (30R),

a mount portion (32) extending from the terminal portion (31) in a first direction orthogonal to a thickness-wise direction (Z-direction) of the terminals (30), the semiconductor chip (20) being mounted on the mount portion (32),

a groove (40) formed in at least the mount portion (32) and extending in the first direction, and

a wall portion (60) extending in the first direction and located at two opposite ends of the groove (40) in a second direction orthogonal to both the thickness-wise direction (Z-direction) and the first direction.

Clause A2

The semiconductor device according to clause A1, in which

the groove (40) is recessed from the terminal head surface (30S) toward the terminal back surface (30R), and

the wall portion (60) includes the terminal head surface (30S).

Clause A3

The semiconductor device according to clause A1 or A2, in which the groove (40) extends from the terminal portion (31) to a distal end part of the mount portion (32).

Clause A4

The semiconductor device according to clause A3, in which the groove (40) is located closer to the terminal portion (31) than a distal edge of the mount portion (32) is.

Clause A5

The semiconductor device according to clause A3, in which the groove (40) is open in the first direction.

Clause A6

The semiconductor device according to any one of clauses A1 to A5, in which the groove (40) extends over both the terminal portion (31) and the mount portion (32).

Clause A7

The semiconductor device according to clause A6, in which the groove (40) is located closer to the mount portion (32) than one of two opposite ends of the terminal portion (31) located away from the mount portion (32) is in the first direction.

Clause A8

The semiconductor device according to clause A1, in which

the mount portion (32) includes a mount portion back surface (32R) defining part of the terminal back surface (30R),

the groove (40) is recessed from the mount portion back surface (32R) toward the terminal head surface (30S), and

the wall portion (60) includes the mount portion back surface (32R).

Clause A9

The semiconductor device according to clause A1, in which

the mount portion (32) includes a mount portion back surface (32R) disposed in the encapsulation resin (50) and defining part of the terminal back surface (30R),

the groove (40) includes

a head surface groove (40S) recessed from the terminal head surface (30S) toward the terminal back surface (30R), and

a back surface groove (40R) recessed from the mount portion back surface (32R) toward the terminal head surface (30S), and

the wall portion includes

a head surface wall portion (60S) including the terminal head surface (30S), and

a back surface wall portion (60R) including the mount portion back surface (32R).

Clause A10

The semiconductor device according to any one of clauses A1 to A9, in which

the groove (40) includes a side surface (41) and a bottom surface (42), and

the side surface (41) is curved toward an inner side of the mount portion (32) as the side surface (41) extends toward the bottom surface (42).

Clause A11

The semiconductor device according to any one of clauses A1 to A10, in which the groove (40) has a depth (H1) of 10 μm or less.

Clause A12

The semiconductor device according to any one of clauses A1 to A11, in which the mount portion (32) includes a part thinner than 1/2 of a thickness of the terminal portion (31).

Clause A13

The semiconductor device according to any one of clauses A1 to A12, in which a length (L2) of the mount portion (32) in the first direction is greater than a length of the terminal portion (31) in the first direction.

Clause A14

The semiconductor device according to any one of clauses A1 to A7, in which

the groove (40) includes a side surface (41) and a bottom surface (42),

the semiconductor chip (20) includes chip terminals (24) electrically connected to the terminals (30), and

the chip terminals (24) are each bonded to the bottom surface (42) of the groove (40).

Clause A15

The semiconductor device according to any one of clauses A1 to A14, in which

the terminal portion (31) includes an inner side surface (31AB) facing the mount portion (32) in the first direction,

the mount portion (32) includes a mount portion back surface (32R) disposed in the encapsulation resin (50) and defining part of the terminal back surface (30R), and

the terminals (30) each include a curved surface (37) connecting the inner side surface (31AB) to the mount portion back surface (32R) between the inner side surface (31AB) and the mount portion back surface (32R).

Clause A16

The semiconductor device according to any one of clauses A1 to A15, in which the terminal portion (31) includes an exposed side surface (31AA) exposed from a side surface (50A) of the encapsulation resin (50).

Clause A17

The semiconductor device according to clause A16, in which the terminals (30) each include a side surface conductive film (35) covering the exposed side surface (31AA) of the terminal portion (31).

Clause A18

The semiconductor device according to any one of clauses A1 to A17, in which the terminals (30) each include a back surface conductive film (34) covering the terminal portion back surface (31R) of the terminal portion (31).

Clause A19

The semiconductor device according to any one of clauses A1 to A18, in which the terminals (30) contain Cu.

Clause A20

The semiconductor device according to any one of clauses A1 to A19, in which the terminals (30) are formed by a metal lead frame.

Clause A21

The semiconductor device according to any one of clauses A1 to A11, in which the terminals (30) each include a projection (38) located at an intermediate part of a distal end surface of the mount portion (32) in the thickness-wise direction (Z-direction), the distal end surface being an end surface of the mount portion (32) in the first direction.

Clause A22

The semiconductor device according to clause A21, in which the projection (38) is located at a central part of the distal end surface in the thickness-wise direction (Z-direction).

Clause A23

The semiconductor device according to clause A21 or A22, in which the projection (38) extends over an entirety of the distal end surface in the second direction.

Clause A24

The semiconductor device according to any one of clauses A21 to A23, in which

the projection (38) includes two side surfaces facing away from each other in the thickness-wise direction (Z-direction), and

the two side surfaces are curved toward each other as the two side surfaces extend toward a distal end of the projection (38).

Clause A25

The semiconductor device according to any one of clauses A21 to A24, in which a ratio of a thickness of the mount portion (32) to a thickness of the terminal portion (31) is greater than 1/2.

Clause A26

The semiconductor device according to clause A25, in which the ratio of the thickness of the mount portion (32) to the thickness of the terminal portion (31) is less than or equal to 4/5.

Clause A27

The semiconductor device according to any one of clauses A21 to A26, in which

the terminals (30) each include a step (39) formed between the mount portion (32) and the terminal portion (31), so that the mount portion back surface (32R) is located closer to the terminal head surface (30S) than the terminal portion back surface (31R) is, and

the step (39) has a dimension less than the thickness of the mount portion (32) in the thickness-wise direction (Z-direction).

Clause A28

The semiconductor device according to clause A27, in which the step (39) includes a curved surface.

Clause B1

A semiconductor device (10), including:

terminals (30), each including a terminal head surface (30S) and a terminal back surface (30R) facing away from the terminal head surface (30S);

a semiconductor chip (20) mounted on the terminals (30); and

an encapsulation resin (50) encapsulating the terminals (30) and the semiconductor chip (20), in which

the terminals (30) each include

a terminal portion (31) including a terminal portion back surface (31R) exposed from the encapsulation resin (50), the terminal portion back surface (31R) being part of the terminal back surface (30R), and

a mount portion (32) extending from the terminal portion (31) in a first direction orthogonal to a thickness-wise direction (Z-direction) of the terminals (30), the semiconductor chip (20) being mounted on the mount portion (32),

the mount portion (32) includes

a base portion (32P) having a flat plate shape and including a mount portion head surface (32S), the mount portion head surface (32S) defining part of the terminal head surface (30S), and

a wall portion (32Q/60) separate from the base portion (32P) and extending upward from the mount portion head surface (32S), and

the wall portion (32Q/60) extends in the first direction, and is located at two opposite ends of the mount portion (32) in a second direction orthogonal to both the thickness-wise direction (Z-direction) and the first direction.

Clause B2

The semiconductor device according to clause B1, in which the wall portion (60) extends over both the terminal portion (31) and the mount portion (32).

Clause B3

The semiconductor device according to clause B1 or B2, in which the mount portion (32) includes a distal end connecting wall (61) located at a distal end part of the mount portion (32) to connect the wall portion (60) located at two sides of the mount portion (32) in the second direction.

Clause B4

The semiconductor device according to any one of clauses B1 to B3, in which the terminals (30) each include a basal end connecting wall (62) connecting the wall portion (60) located at two sides in the second direction.

Clause B5

The semiconductor device according to any one of clauses B1 to B4, in which the wall portion (60) is formed by a metal film.

Clause B6

The semiconductor device according to any one of clauses B1 to B5, in which the mount portion (32) includes

a mount portion back surface (32R) disposed in the encapsulation resin (50) and defining part of the terminal back surface (30R), and

a back surface wall portion (32Q/60) separate from the base portion (32P), the back surface wall portion (32Q/60) extending in the first direction and being located at two opposite ends of the mount portion back surface (32R) in the second direction.

Clause B7

A semiconductor device (10), including:

terminals (30), each including a terminal head surface (30S) and a terminal back surface (30R) facing away from the terminal head surface (30S);

a semiconductor chip (20) mounted on the terminals (30); and

an encapsulation resin (50) encapsulating the terminals (30) and the semiconductor chip (20), in which

the terminals (30) each include

a terminal portion (31) including a terminal portion back surface (31R) exposed from the encapsulation resin (50), the terminal portion back surface (31R) being part of the terminal back surface (30R), and

a mount portion (32) extending from the terminal portion (31) in a first direction orthogonal to a thickness-wise direction (Z-direction) of the terminals (30), the semiconductor chip (20) being mounted on the mount portion (32),

the mount portion (32) includes

a mount portion back surface (32R) disposed in the encapsulation resin (50) and defining part of the terminal back surface (30R),

a base portion (32P) having a flat plate shape and including the mount portion back surface (32R) and a mount portion head surface (32S), the mount portion head surface (32S) defining part of the terminal head surface (30S), and

a wall portion (32Q/60) separate from the base portion (32P) and extending downward from the mount portion back surface (32R), and

the wall portion (32Q/60) extends in the first direction, and is located at two opposite ends of the mount portion (32) in a second direction orthogonal to both the thickness-wise direction (Z-direction) and the first direction.

Clause B8

The semiconductor device according to clause B7, in which the mount portion (32) includes a distal end connecting wall (61) located at a distal end part of the mount portion (32) to connect the wall portion (60) located at two sides of the mount portion (32) in the second direction.

Clause B9

The semiconductor device according to clause B7 or B8, in which the mount portion (32) includes a basal end connecting wall (62) located at a basal end part of the mount portion (32) to connect the wall portion (60) located at two sides in the second direction.

Clause B10

The semiconductor device according to any one of clauses B7 to B9, in which the wall portion (32Q/60) is formed by a metal film.

Clause C1

A method for manufacturing a semiconductor device (10), the method including:

preparing terminals (30), each including a terminal head surface (30S) and a terminal back surface (30R) facing away from the terminal head surface (30S);

mounting a semiconductor chip (20) on the terminals (30); and

forming an encapsulation resin (50) to encapsulate the terminals (30) and the semiconductor chip (20), in which

the preparing the terminals (30) includes

forming a terminal portion (31) and a mount portion (32), the mount portion (32) extending from the terminal portion (31) in a first direction orthogonal to a thickness-wise direction (Z-direction) of the terminals (30), the mount portion (32) being configured to receive the semiconductor chip (20), and

forming a groove (40) in the mount portion (32) by etching at least the mount portion (32), and

the terminals (30) each include a wall portion (60) extending in the first direction and located at two opposite ends of the groove (40) in a second direction orthogonal to both the thickness-wise direction (Z-direction) and the first direction.

Clause C2

The method according to clause C1, further including cleaning the terminals (30) after forming the groove (40).

Clause C3

The method according to clause C1 or C2, in which the preparing the terminals (30) includes

preparing a lead frame (830) including terminals (30), and

forming the groove (40) by partially etching a region of the lead frame (830) corresponding to at least the mount portion (32).

Clause C4

The method according to any one of clauses C1 to C3, in which, in the preparing the terminals (30), the groove (40) is formed after forming the mount portion (32).

Clause C5

The method according to any one of clauses C1 to C4, in which the forming the groove (40) includes forming the groove (40) recessed from a mount portion head surface (32S) toward a mount portion back surface (32R), the mount portion head surface (32S) serving as a region of the lead frame (830) corresponding to at least the mount portion (32).

Clause C6

The method according to any one of clauses C1 to C4, in which the forming the groove (40) includes forming the groove (40) recessed from a mount portion back surface (32R) toward a mount portion head surface (32S), the mount portion back surface (32R) serving as a region of the lead frame (830) corresponding to the mount portion (32).

Clause C7

The method according to any one of clauses C1 to C4, in which the preparing the terminals (30) includes

forming a head surface groove (40S) recessed from a mount portion head surface (32S) toward a mount portion back surface (32R), the mount portion head surface (32S) serving as a region of the lead frame (830) corresponding to at least the mount portion (32), and

forming a back surface groove (40R) recessed from the mount portion back surface (32R) toward the mount portion head surface (32S), the mount portion back surface (32R) serving as a region of the lead frame (830) corresponding to the mount portion (32).

Clause C8

The method according to clause C1 or C2, in which

the preparing the terminals (30) includes

preparing a metal plate (930) including a head surface (930S), and a back surface (930R) facing away from the head surface (930S), and

selectively removing the metal plate (930) by etching the metal plate (930) from both the head surface (930S) and the back surface (930R), and

the selectively removing the metal plate (930) forms a distal end surface and a projection (38), the distal end surface being an end surface of the metal plate (930) in the first direction orthogonal to the thickness-wise direction (Z-direction), the projection (38) being located at an intermediate part of the distal end surface in the thickness-wise direction (Z-direction).

Clause C9

The method according to clause C8, in which the preparing the terminals (30) includes forming a recess (931) by etching part of the head surface (930S).

Clause C10

The method according to clause C9, in which the selectively removing the metal plate (930) includes further etching the recess (931) from the head surface (930S).

Clause C11

The method according to any one of clauses C8 to C10, in which the preparing the terminals (30) includes, by etching the back surface (930R), forming

a terminal portion (31) including a terminal portion back surface (31R) facing a same direction as the back surface (930R) in the thickness-wise direction (Z-direction),

a mount portion (32) extending from the terminal portion (31) in the first direction, and

a step (39) between the mount portion (32) and the terminal portion (31), the step (39) being located closer to the head surface (930S) than the terminal portion back surface (31R) of the terminal portion (31) is.

Clause C12

The method according to any one of clauses C1 to C11, in which the preparing the terminals (30) includes forming the terminal portion (31) and the mount portion (32), so that a ratio of a thickness of the mount portion (32) to a thickness of the terminal portion (31) is greater than 1/2.

Clause C13

The method according to clause C12, in which the preparing the terminals (30) includes forming the terminal portion (31) and the mount portion (32), so that the ratio of the thickness of the mount portion (32) to the thickness of the terminal portion (31) is less than or equal to 4/5.

Clause D1

A method for manufacturing a semiconductor device (10), the method including:

preparing terminals (30), each including a terminal head surface (30S) and a terminal back surface (30R) facing away from the terminal head surface (30S);

mounting a semiconductor chip (20) on the terminals (30); and

forming an encapsulation resin (50) to encapsulate the terminals (30) and the semiconductor chip (20), in which

the preparing the terminals (30) includes

forming a terminal portion (31),

forming a mount portion (32) extending from the terminal portion (31) in a first direction orthogonal to a thickness-wise direction (Z-direction) of the terminals (30), the mount portion (32) including a base portion (32P), the base portion (32P) having a flat plate shape and being configured to receive the semiconductor chip (20), and

forming a wall portion (60) separate from the base portion (32P) and extending upward from the terminal head surface (30S) in at least the mount portion (32), and

the wall portion (60) extends in the first direction, and is located at two opposite ends of the mount portion (32) in a second direction orthogonal to both the thickness-wise direction (Z-direction) and the first direction.

Clause D2

The method according to clause D1, further including cleaning the terminals (30) after forming the wall portion (60).

Clause D3

The method according to clause D1 or D2, in which, in the forming the wall portion (60), a metal film is sputtered on the terminal head surface (30S) to form the wall portion (60).

Clause D4

The method according to any one of clauses D1 to D3, in which

the mount portion (32) includes a mount portion back surface (32R) disposed in the encapsulation resin (50) and defining part of the terminal back surface (30R), and

the preparing the terminal (30) includes forming a back surface wall portion (60) extending in the first direction, the back surface wall portion (60) being located at two opposite ends of the mount portion back surface (32R) in the second direction.

Clause D5

A method for manufacturing a semiconductor device (10), the method including:

preparing terminals (30), each including a terminal head surface (30S) and a terminal back surface (30R) facing away from the terminal head surface (30S);

mounting a semiconductor chip (20) on the terminals (30); and

forming an encapsulation resin (50) to encapsulate the terminals (30) and the semiconductor chip (20), in which

the preparing the terminals (30) includes

forming a terminal portion (31) and a mount portion (32), the mount portion (32) extending from the terminal portion (31) in a first direction orthogonal to a thickness-wise direction (Z-direction) of the terminals (30), the mount portion (32) including a base portion (32P), the base portion (32P) having a flat plate shape and being configured to receive the semiconductor chip (20), and

forming a wall portion (60) separate from the base portion (32P),

the mount portion (32) includes a mount portion back surface (32R) disposed in the encapsulation resin (50) and defining part of the terminal back surface (30R), and

the wall portion (60) extends downward from the mount portion back surface (32R), and is located at two opposite ends of the mount portion back surface (32R) in the second direction, and extends in the first direction.

Clause D6

The method according to clause D5, further including cleaning the terminals (30) after forming the wall portion (60).

Clause D7

The method according to clause D5 or D6, in which, in the forming the wall portion (60), a metal film is sputtered on the mount portion back surface (32R) to form the wall portion (60).

The above descriptions are merely exemplary. One skilled in the art would recognize the potential for a wide variety of combinations and substitutions of the elements and methods (manufacturing processes) in addition to those illustrated to describe the techniques of this disclosure. Any substitutions, modifications, and variations within the scope of the claims are intended to be encompassed in the present disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
terminals, each including a terminal head surface and a terminal back surface facing away from the terminal head surface;
a semiconductor chip mounted on the terminals; and
an encapsulation resin encapsulating the terminals and the semiconductor chip, wherein
the terminals each include
a terminal portion including a terminal portion back surface exposed from the encapsulation resin, the terminal portion back surface being part of the terminal back surface,
a mount portion extending from the terminal portion in a first direction orthogonal to a thickness-wise direction of the terminals, the semiconductor chip being mounted on the mount portion,
a groove formed in at least the mount portion and extending in the first direction, and
a wall portion extending in the first direction and located at two opposite ends of the groove in a second direction orthogonal to both the thickness-wise direction and the first direction.

2. The semiconductor device according to claim 1, wherein
the groove is recessed from the terminal head surface toward the terminal back surface, and
the wall portion includes the terminal head surface.

3. The semiconductor device according to claim 1, wherein the groove extends from the terminal portion to a distal end part of the mount portion.

4. The semiconductor device according to claim 3, wherein the groove is located closer to the terminal portion than a distal edge of the mount portion is.

5. The semiconductor device according to claim 3, wherein the groove is open in the first direction.

6. The semiconductor device according to claim 1, wherein the groove extends over both the terminal portion and the mount portion.

7. The semiconductor device according to claim 6, wherein the groove is located closer to the mount portion than one of two opposite ends of the terminal portion located away from the mount portion is in the first direction.

8. The semiconductor device according to claim 1, wherein
the mount portion includes a mount portion back surface defining part of the terminal back surface,
the groove is recessed from the mount portion back surface toward the terminal head surface, and
the wall portion includes the mount portion back surface.

9. The semiconductor device according to claim 1, wherein
the mount portion includes a mount portion back surface disposed in the encapsulation resin and defining part of the terminal back surface,
the groove includes
a head surface groove recessed from the terminal head surface toward the terminal back surface, and
a back surface groove recessed from the mount portion back surface toward the terminal head surface, and
the wall portion includes
a head surface wall portion including the terminal head surface, and
a back surface wall portion including the mount portion back surface.

10. The semiconductor device according to claim 1, wherein the groove includes
a side surface,
a bottom surface, and
a curved surface located between the side surface and the bottom surface, the curved surface being curved toward an inner side of the mount portion as the curved surface extends toward the bottom surface.

11. The semiconductor device according to claim 1, wherein the groove has a depth of 10 μm or less.

12. The semiconductor device according to claim 1, wherein the mount portion includes a part thinner than 1/2 of a thickness of the terminal portion.

13. The semiconductor device according to claim 1, wherein a length of the mount portion in the first direction is greater than a length of the terminal portion in the first direction.

14. The semiconductor device according to claim 1, wherein
the groove includes a side surface and a bottom surface,
the semiconductor chip includes chip terminals electrically connected to the terminals, and
the chip terminals are each bonded to the bottom surface of the groove.

15. The semiconductor device according to claim 1, wherein
the terminal portion includes an inner side surface facing the mount portion in the first direction,
the mount portion includes a mount portion back surface disposed in the encapsulation resin and defining part of the terminal back surface, and
the terminals each include a curved surface connecting the inner side surface to the mount portion back surface between the inner side surface and the mount portion back surface.

16. The semiconductor device according to claim 1, wherein the terminal portion includes an exposed side surface exposed from a side surface of the encapsulation resin.

17. The semiconductor device according to claim 16, wherein the terminals each include a side surface conductive film covering the exposed side surface of the terminal portion.

18. The semiconductor device according to claim 1, wherein the terminals each include a back surface conductive film covering the terminal portion back surface of the terminal portion.

19. The semiconductor device according to claim 1, wherein the terminals contain Cu.
